(19) United States
(12) Patent Application Publication
(10) Pub. No.: US 2026/0107522 A1
(43) Pub. Date: Apr. 16, 2026

(54) POWER SEMICONDUCTOR DEVICES HAVING ORTHOGONAL GATE ELECTRODES AND OHMIC LINES FOR IMPROVED ON-STATE RESISTANCE PERFORMANCE

(71) Applicant: Wolfspeed, Inc., Durham, NC (US)

(72) Inventors: Joohyung Kim, Cary, NC (US); Jae-Hyung Park, Apex, NC (US); Sei-Hyung Ryu, Cary, NC (US); Naeem Islam, Fuquay-Varina, NC (US); Woongsun Kim, Cary, NC (US); Ping-Ju Chuang, Morrisville, NC (US)

(21) Appl. No.: 19/209,073

(22) Filed: May 15, 2025

Related U.S. Application Data
(63) Continuation-in-part of application No. 18/912,690, filed on Oct. 11, 2024.

(51) Int. Cl. H10D 62/10; H10D 30/66; H10D 62/13; H10D 62/832; H10D 64/62

(52) U.S. Cl. CPC H10D 62/109; H10D 30/668; H10D 62/127; H10D 62/155; H10D 62/8325; H10D 64/62

(57) ABSTRACT

A semiconductor device comprises a semiconductor layer structure comprising a drift region having a first conductivity type, a first gate electrode on the semiconductor layer structure that extends along a first longitudinal axis, a second gate electrode on the semiconductor layer structure that extends along a second longitudinal axis, and a first ohmic line that extends continuously in the semiconductor layer structure along a first transverse axis. The first and second longitudinal axes cross the first transverse axis when the semiconductor device is viewed from above.

### CROSS-REFERENCE TO RELATED APPLICATION

The present application claims priority under 35 U.S.C. § 120 as a continuation-in-part of U.S. patent application Ser. No. 18/912,690, filed Oct. 11, 2024, the entire content of which is incorporated herein by reference as if set forth in its entirety.

### FIELD OF THE INVENTION

The present invention relates to power semiconductor devices and, more particularly, to gate-controlled power semiconductor devices

### BACKGROUND

The Metal Oxide Semiconductor Field Effect Transistor (“MOSFET”) is a well-known type of semiconductor transistor that may be used as a switch. A MOSFET is a three terminal device that has gate, drain and source terminals and a semiconductor body. The semiconductor body is referred to herein as a “semiconductor layer structure” and may include one or more semiconductor layers/regions. A source region and a drain region that each have a first conductivity type are formed in the semiconductor layer structure and are separated from each other by a channel region that has a second conductivity type. A gate electrode is disposed adjacent the channel region and separated from the channel region by a thin oxide layer. A MOSFET may be turned on or off by setting a bias voltage that is applied to the gate electrode to be above or below a threshold value (which may be a negative voltage). When a MOSFET is turned on (i.e., it is in its “on-state”), current is conducted through the channel region between the source and drain regions. When the bias voltage is reduced below the threshold level, the current ceases to conduct through the channel region.

An n-type MOSFET has source and drain regions that have n-type (electron) conductivity and a channel region that has p-type (hole) conductivity. An n-type MOSFET turns on when the gate bias voltage that is applied to the gate electrode is sufficient to create a conductive n-type inversion layer in the p-type channel region, thereby electrically connecting the n-type source and drain regions and allowing for majority carrier conduction therebetween. A p-type MOSFET has a p-type source and drain regions and an n-type channel region and turns on when a gate bias voltage is applied to the gate electrode that is sufficient to create a conductive p-type inversion layer in the n-type channel region to electrically connect the p-type source and drain regions. Herein, the terms “first conductivity type” and “second conductivity type” are used to indicate either n-type or p-type conductivity, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

Because the gate electrode of a MOSFET is insulated from the channel region by the gate oxide layer, minimal gate current is required to maintain the MOSFET in its on-state or to switch the MOSFET between its off-state and its on-state. The gate current is kept small during switching because the gate forms a capacitor with the channel region. Thus, only minimal charging and discharging current is required during switching, allowing for less complex gate drive circuitry and faster switching speeds. MOSFETs may be stand-alone devices or may be combined with other devices. For example, an Insulated Gate Bipolar Transistor (“IGBT”) is a semiconductor device that includes both a MOSFET and a Bipolar Junction Transistor (“BJT”) that combines the high impedance gate electrode of the MOSFET with the small on-state conduction losses that may be provided by a BJT.

In many applications, MOSFETs may need to carry large currents and/or be capable of blocking high voltages (e.g., hundreds or thousands of volts of electric potential). Such MOSFETs are often referred to as “power” MOSFETs. Power MOSFETs are often fabricated from wide band-gap semiconductor materials (herein, the term “wide band-gap semiconductor” encompasses any semiconductor having a band-gap of at least 1.4 eV). Power MOSFETs and other power semiconductor devices are often formed in silicon carbide (“SiC”), which has a number of advantageous characteristics including, for example, a high electric field breakdown strength, high thermal conductivity, high electron mobility, high melting point and high-saturated electron drift velocity.

MOSFETs can have a lateral structure or a vertical structure. In a device having a lateral structure, the drain, gate and source terminals are on the same major surface (i.e., top or bottom) of a semiconductor layer structure. In contrast, in a device having a vertical structure, at least one terminal is provided on each major surface of the semiconductor layer structure (e.g., the source and gate may be on the top surface of the semiconductor layer structure and the drain may be on the bottom surface of the semiconductor layer structure).

The semiconductor layer structure of a power semiconductor device includes an “active region” in which one or more functional semiconductor devices are formed. The active region acts as a main junction for blocking voltage during reverse bias (off-state) operation and for providing current flow during forward bias (on-state) operation. The power semiconductor device may also have an edge termination structure such as guard rings or a junction termination extension in a termination region of the semiconductor layer structure that is adjacent (and typically surrounding) the active region. The edge termination structure may, among other things, reduce electric field crowding effects that can occur at the outer edges of a power semiconductor device. Typically, multiple power semiconductor devices are formed in/on a common wafer, and each power semiconductor device will typically have its own edge termination structure. After the wafer is fully processed, the resultant structure may be diced to separate the individual edge-terminated power semiconductor devices. Each power semiconductor device may have a unit cell structure in which the active region of each power semiconductor device includes a plurality of individual “unit cell” devices that are electrically connected in parallel and that together function as a single power semiconductor device.

Vertical gate-controlled power semiconductor devices can have a planar gate electrode design in which the gate electrodes are formed on top of the semiconductor layer structure or, alternatively, may have the gate electrodes formed within gate trenches in the semiconductor layer structure, which are typically referred to as gate trench devices. With the planar gate electrode design, the channel region of each unit cell transistor is horizontally disposed underneath the gate electrode. In contrast, in gate trench devices, the channels are typically vertically disposed adjacent sidewalls of the gate electrodes.

One failure mechanism for a power MOSFET is the so-called “breakdown” of the gate oxide layer. The gate oxide layer is subjected to high electric fields during normal device operation. The high electric fields degrade the gate oxide layer over time, and may eventually result in failure of the device. When gate trench MOSFETs operate in reverse blocking operation (i.e., when the MOSFET is in its off-state), the source terminal of the MOSFET is typically grounded, the gate terminal is typically grounded or at a negative bias voltage, and the drain terminal is typically at a high positive voltage. During such reverse blocking operations, high electric fields extend upwardly from the drain terminal (which is on the lower surface of the semiconductor layer structure) toward the upper surface of the semiconductor layer structure. Thus, under reverse blocking operation, the portions of the gate oxide layers lining the bottoms of the gate trenches experience the highest electric field levels. The stress on the gate oxide layer caused by these electric fields generates defects in the oxide material, and these defects build up over time. When the concentration of defects reaches a critical value, a so-called “percolation path” may be created through the gate oxide layer that electrically connects the gate electrode to the source region, thereby creating a short-circuit that can destroy the device. The “lifetime” of a gate oxide layer (i.e., how long the device can be operated before breakdown occurs) is a function of, among other things, the magnitude of the electric field that the gate oxide layer is subjected to and the length of time for which the electric field is applied. Generally speaking, the relationship between the magnitude of the applied electric field and gate oxide lifetime may be generally linear when the gate oxide lifetime is plotted on a logarithmic scale, meaning that as the electric field level is increased, the lifetime of the gate oxide layer decreases exponentially.

### SUMMARY

Pursuant to some embodiments of the present invention, semiconductor device are provided that comprise a semiconductor layer structure comprising a drift region having a first conductivity type, a first gate electrode on the semiconductor layer structure that extends along a first longitudinal axis, a second gate electrode on the semiconductor layer structure that extends along a second longitudinal axis, and a first ohmic line that extends continuously in the semiconductor layer structure along a first transverse axis. The first and second longitudinal axes cross the first transverse axis when the semiconductor device is viewed from above.

In some embodiments, the first longitudinal axis extends in parallel to the second longitudinal axis. In some embodiments, the first transverse axis crosses the first longitudinal axis at an angle of 90°.

In some embodiments, the semiconductor device may further comprise a dielectric layer that extends continuously in a direction parallel to the first transverse axis to cover the first gate electrode and the second gate electrode and an upper surface of the semiconductor layer structure that is in between the first gate electrode and the second gate electrode.

In some embodiments, the first gate electrode is in a first gate trench in the semiconductor layer structure and the second gate electrode is in a second gate trench in the semiconductor layer structure. In some embodiments, the first gate trench and the second gate trench each have a respective first end that is adjacent the first ohmic line. In some embodiments, the semiconductor device may further comprise a third gate electrode that extends along a third longitudinal axis in a third gate trench in the semiconductor layer structure and a fourth gate electrode that extends along a fourth longitudinal axis in a fourth gate trench in the semiconductor layer structure, where the first longitudinal axis is colinear with the third longitudinal axis and the second longitudinal axis is colinear with the fourth longitudinal axis. In some embodiments, the first ohmic line is in between the first gate trench and the third gate trench and is in between the second gate trench and the fourth gate trench when the semiconductor device is viewed from above.

In some embodiments, the semiconductor device may further comprise a second ohmic line that extends continuously in the semiconductor layer structure along a second transverse axis, wherein the first and second longitudinal axes cross the second transverse axis when the semiconductor device is viewed from above. In such embodiments, the first transverse axis may extend in parallel to the second transverse axis. In some embodiments, the first gate electrode and the second gate electrode may be positioned between the first ohmic line and the second ohmic line when the semiconductor device is viewed from above.

In some embodiments, a first portion of the semiconductor layer structure that is in between the first gate trench and the second gate trench comprises a drift region having a first conductivity type, a source region having the first conductivity type and a well region having a second conductivity that is in between the drift region and the source region. In such embodiments, the first longitudinal axis may extend in a first direction, and the semiconductor device may also be configured so that during on-state operation a source-drain current flows in the first direction through the source region in the first portion of the semiconductor layer structure.

In some embodiments, the semiconductor device may further comprise a silicide layer on the source region and a dielectric layer on the silicide layer, where the silicide layer directly contacts both the source region and the dielectric layer. In such embodiments, the silicide layer may extend continuously on an upper surface of the source region from a first sidewall of the first gate trench to a first sidewall of the second gate trench.

In some embodiments, the semiconductor device may further comprise a supplemental gate electrode that extends in a first supplemental gate trench in the semiconductor layer structure, the supplemental gate electrode having a longitudinal axis that is perpendicular to the first and second longitudinal axes. In such embodiments, a first end of the first gate electrode contacts the supplemental gate electrode and a first end of the second gate electrode contacts the supplemental gate electrode. In these embodiments, the supplemental gate electrode may extend along a second transverse axis that is parallel to the first transverse axis. In some embodiments, the semiconductor layer structure may comprise a drift region having a first conductivity type, a source region having the first conductivity type, a well region having a second conductivity that is in between the drift region and the source region, and a trench shield having the second conductivity type that extends underneath the first gate trench, the second gate trench and the supplemental gate trench. In such embodiments, the semiconductor layer structure may further comprise a trench shield connection pattern having the second conductivity type that extends along a sidewall of the supplemental gate trench.

In some embodiments, a width of a portion of the semiconductor layer structure that is in between the first gate trench and the second gate trench is less than a width of the first gate trench.

Pursuant to some embodiments of the present invention, semiconductor device are provided that comprise a semiconductor layer structure comprising a drift region having a first conductivity type, a source region having the first conductivity type and a well region having a second conductivity type between the drift region and the source region. These semiconductor devices further comprise a first gate electrode on the semiconductor layer structure that has a first longitudinal axis that extends in a first direction, a second gate electrode on the semiconductor layer structure that has a second longitudinal axis that extends in the first direction, and a dielectric layer that extends continuously on the semiconductor layer structure in a second direction, where the dielectric layer crosses the first gate electrode, the second gate electrode and a first portion of the source region that is in between the first gate electrode and the second gate electrode.

In some embodiments, the second direction is perpendicular to first direction.

In some embodiments, the dielectric layer directly contacts the first portions of the source region.

In some embodiments, the semiconductor device may further comprise a silicide layer on the first portions of the source region, and the dielectric layer directly contacts the silicide layer.

In some embodiments, the semiconductor device may further comprise a source metallization, wherein the semiconductor layer structure further comprises a first ohmic line that extends in a second direction that is perpendicular to the first direction, wherein the source metallization directly contacts the first ohmic line. In some embodiments, the semiconductor layer structure may also include a second ohmic line that extends in the second direction, and the dielectric layer may cover portions of the semiconductor layer structure that are in between the first ohmic line and the second ohmic line. In some embodiments, the first gate electrode and the second gate electrode may be positioned between the first ohmic line and the second ohmic line when the semiconductor device is viewed from above.

In some embodiments, the first gate electrode is in a first gate trench in the semiconductor layer structure and the second gate electrode is in a second gate trench in the semiconductor layer structure, the semiconductor device further comprising a third gate electrode that is in a third gate trench in the semiconductor layer structure, and a fourth gate electrode that is in a fourth gate trench in the semiconductor layer structure. In such embodiments, the first gate trench and the second gate trench each have a respective first end that is adjacent the first ohmic line. In some embodiments, a longitudinal axis of the first gate trench is colinear with a longitudinal axis of the third gate trench, and a longitudinal axis of the second gate trench is colinear with a longitudinal axis of the fourth gate trench. In some embodiments, the first ohmic line is in between the first gate trench and the third gate trench and the first ohmic line is also in between the second gate trench and the fourth gate trench.

In some embodiments, a width of a portion of the semiconductor layer structure that is in between the first gate trench and the second gate trench is less than a width of the first gate trench.

In some embodiments, the first gate trench has a first longitudinal axis that extends in a first direction, and the semiconductor device is configured so that during on-state operation a source-drain current flows in the first direction through the source region in a first portion of the semiconductor layer structure that is in between the first gate trench and the second gate trench.

In some embodiments, the semiconductor device may further comprise a supplemental gate electrode that extends in a first supplemental gate trench in the semiconductor layer structure, the supplemental gate electrode having a longitudinal axis that is perpendicular to a first longitudinal axis of the first gate trench. In such embodiments, a first end of the first gate electrode contacts the supplemental gate electrode.

Pursuant to some embodiments of the present invention, semiconductor device are provided that comprise a semiconductor layer structure comprising a source region having the first conductivity type, a silicide layer on the source region, and a dielectric layer on the silicide layer so that the silicide layer directly contacts both the source region and the dielectric layer.

In some embodiments, the semiconductor device may further comprise a first gate electrode that has a first longitudinal axis that extends in a first direction and a second gate electrode that has a second longitudinal axis that extends in the first direction.

In some embodiments, the semiconductor device may further comprise a first ohmic line that extends continuously in the semiconductor layer structure along a first transverse axis and a second ohmic line that extends continuously in the semiconductor layer structure along a second transverse axis, where the first longitudinal axis extends perpendicular to both the first transverse axis and the second transverse axis when the semiconductor device is viewed from above. In some embodiments, the first silicide layer covers an entirety of an upper surface of a first portion of the source region that is in between the first gate electrode, the second gate electrode, the first ohmic line and the second ohmic line.

In some embodiments, the first gate electrode is in a first gate trench in the semiconductor layer structure and the second gate electrode is in a second gate trench in the semiconductor layer structure. In some embodiments, a width of a portion of the semiconductor layer structure that is in between the first gate trench and the second gate trench is less than a width of the first gate trench.

Pursuant to still further embodiments of the present invention, semiconductor device are provided that comprise a semiconductor layer structure comprising a drift region having a first conductivity type, a source region having the first conductivity type and a well region having a second conductivity type between the drift region and the source region, a first gate electrode on the semiconductor layer structure that has a first longitudinal axis that extends in a first direction, a second gate electrode on the semiconductor layer structure that has a second longitudinal axis that extends in the first direction, the second gate electrode adjacent the first gate electrode in a second direction that is perpendicular to the first direction, and a source metallization on an upper surface of the semiconductor layer structure, where the source metallization has a plurality of downwardly-extending protrusions that directly contact an upper surface of the semiconductor layer structure, where the downwardly-extending protrusions have respective longitudinal axes that extend in the second direction.

In some embodiments, a dielectric layer completely covers a portion of the upper surface of the semiconductor layer structure that is in between the first gate electrode and the second gate electrode.

In some embodiments, a first gate electrode and the second gate electrode are in between first and second of the downwardly-extending protrusions when the semiconductor device is viewed from above.

In some embodiments, the first gate electrode is in a first gate trench in the semiconductor layer structure and the second gate electrode is in a second gate trench in the semiconductor layer structure. In some embodiments, the semiconductor device may further comprise a third gate electrode that extends along a third longitudinal axis in a third gate trench in the semiconductor layer structure and a fourth gate electrode that extends along a fourth longitudinal axis in a fourth gate trench in the semiconductor layer structure, where the first longitudinal axis is colinear with the third longitudinal axis and the second longitudinal axis is colinear with the fourth longitudinal axis. In some embodiments, a first of the downwardly-extending protrusions is in between the first gate trench and the third gate trench and is in between the second gate trench and the fourth gate trench when the semiconductor device is viewed from above. In some embodiments, the semiconductor device may further comprise a first ohmic line in the semiconductor layer structure, wherein the first of the downwardly-extending protrusions directly contacts the first ohmic line.

Pursuant to some embodiments of the present invention, semiconductor device are provided that comprise a semiconductor layer structure comprising a drift region having a first conductivity type, a source region having the first conductivity type and a well region having a second conductivity type between the drift region and the source region. These semiconductor devices further comprise a first gate trench on the semiconductor layer structure that has a first longitudinal axis that extends in a first direction, a second gate trench on the semiconductor layer structure that has a second longitudinal axis that extends in the first direction, the second gate trench adjacent the first gate trench, and a first ohmic line in the semiconductor layer structure that has a third longitudinal axis that extends in a second direction, and a second ohmic line in the semiconductor layer structure that has a fourth longitudinal axis that extends in the second direction. A portion of the source region that is within a first region that is in between the first gate trench, the second gate trench, the first ohmic line and the second ohmic line when the semiconductor device is viewed in plan view completely covers a portion of the well region that is within the first region.

In some embodiments, the semiconductor device may further comprise a silicide layer on an upper surface of the source region in the first region.

In some embodiments, the semiconductor device may further comprise a dielectric layer that completely covers an upper surface of the source region in the first region.

In some embodiments, the semiconductor device may further comprise a third gate electrode that extends along a third longitudinal axis in a third gate trench in the semiconductor layer structure and a fourth gate electrode that extends along a fourth longitudinal axis in a fourth gate trench in the semiconductor layer structure, where the first longitudinal axis is colinear with the third longitudinal axis and the second longitudinal axis is colinear with the fourth longitudinal axis. In some embodiments, the first ohmic line is in between the first gate trench and the third gate trench and is in between the second gate trench and the fourth gate trench when the semiconductor device is viewed from above.

In some embodiments, a width of a portion of the semiconductor layer structure that is in between the first gate trench and the second gate trench is less than a width of the first gate trench.

Pursuant to some embodiments of the present invention, semiconductor device are provided that comprise a semiconductor layer structure comprising a drift region having a first conductivity type, a source region having the first conductivity type and a well region having a second conductivity type between the drift region and the source region, a first gate electrode in the semiconductor layer structure, the first gate electrode having a first longitudinal axis that extends in a first direction, and a second gate electrode in the semiconductor layer structure, the second gate electrode having a second longitudinal axis that extends in the first direction, the second gate electrode adjacent the first gate electrode. The semiconductor device is configured so that during on-state operation a source-drain current flows in the first direction through a first portion of the source region that is in between the first gate electrode and the second gate electrode.

In some embodiments, the semiconductor device may further comprise a silicide layer on the first portion of the source region and a dielectric layer on the silicide layer, where the silicide layer directly contacts both the first portion of the source region and the dielectric layer.

Pursuant to some embodiments of the present invention, semiconductor devices are provided that comprise a semiconductor layer structure comprising a drift region having a first conductivity type, a first gate electrode on the semiconductor layer structure that extends along a first longitudinal axis, a second gate electrode on the semiconductor layer structure that extends along a second longitudinal axis, a first ohmic line that extends continuously in the semiconductor layer structure along a first transverse axis, a second ohmic line that extends continuously in the semiconductor layer structure along a second transverse axis that is parallel to the first transverse axis, and a dielectric layer that completely covers an upper surface of a first region of the semiconductor layer structure that is in between the first and second gate electrodes and the first and second ohmic lines.

In some embodiments, an entirety of the upper surface of the first region of the semiconductor layer structure is a source region that has the first conductivity type.

In some embodiments, the first longitudinal axis crosses the first transverse axis at an angle of 90° when the semiconductor device is viewed from above.

In some embodiments, the semiconductor device may further comprise a source metallization that directly contacts the entirety of first region of the semiconductor layer structure. In some embodiments, the source metallization also directly contacts the first ohmic line and the second ohmic line.

Pursuant to further embodiments of the present invention, semiconductor devices are provided that comprise a semiconductor layer structure comprising a drift region having a first conductivity type. A first gate electrode is provided on the semiconductor layer structure that extends along a first longitudinal axis above the drift region and a second gate electrode is provided on the semiconductor layer structure, the second gate electrode comprising a plurality of second gate electrode segments that are spaced-apart from each other along a second longitudinal axis above the drift region. The semiconductor device further comprise a first ohmic line that extends in the semiconductor layer structure along a first transverse axis. The first and second longitudinal axes cross the first transverse axis when the semiconductor device is viewed from above.

In some embodiments, the first longitudinal axis is parallel to the second longitudinal axis. In some embodiments, the first transverse axis is perpendicular to the first longitudinal axis. In some embodiments, the first gate electrode comprises a plurality of first gate electrode segments that are spaced-apart from each other along the first longitudinal axis, and the first ohmic line extends continuously in the semiconductor layer structure between a first of the plurality of first gate electrode segments and a second of the plurality of first gate electrode segments.

In some embodiments, the first ohmic line comprises a plurality of first ohmic line segments that are spaced-apart from each other along the first transverse axis. In some embodiments, the first gate electrode extends continuously in the semiconductor layer structure between a first of the plurality of first ohmic line segments and a second of the plurality of first ohmic line segments.

In some embodiments, the semiconductor device further comprises a second ohmic line that extends in the semiconductor layer structure along a second transverse axis that is parallel to the first transverse axis. In such embodiments, the semiconductor layer structure may further comprise a source region that has the first conductivity type, where a first portion of the source region that is in between the first gate electrode, the second gate electrode, the first ohmic line and the second ohmic line when the semiconductor device is viewed from above directly contacts a dielectric layer that covers the first portion of the source region. In some embodiments, the semiconductor layer structure further comprises a source region that has the first conductivity type, where a first portion of the source region is in between the first gate electrode, the second gate electrode, the first ohmic line and the second ohmic line when the semiconductor device is viewed from above, and the semiconductor device further comprises a silicide layer that is directly on the first portion of the source region, and a dielectric layer that directly contacts the silicide layer. In some embodiments, the silicide layer extends continuously on an upper surface of the first portion of the source region in between the first and second ohmic lines.

In some embodiments, the semiconductor layer structure further comprises a source region that has the first conductivity type, where a first portion of the source region that is in between the first gate electrode, the second gate electrode, the first ohmic line and the second ohmic line when the semiconductor device is viewed from above and a well region having a second conductivity type that is in between the drift region and the first portion of the source region. In such embodiments, the semiconductor device may be configured so that during on-state operation a source-drain current flows from the first ohmic line through the first portion of the source region toward the second ohmic line. In some embodiments, the semiconductor device further comprises a silicide layer that is on the first portion of the source region, and the semiconductor device is configured so that during on-state operation a source-drain current flows through the silicide layer.

In some embodiments, the semiconductor device may further comprise a third gate electrode that extends along a third longitudinal axis that is perpendicular to the first and second longitudinal axes. In some embodiments, the third gate electrode may extend continuously along the third longitudinal axis to intersect both the first gate electrode and the second gate electrode. In some embodiments, the semiconductor layer structure further comprises a plurality of source regions that have the first conductivity type, each source region having a U-shape when the semiconductor device is viewed from above. In some embodiments, each source region having the U-shape has first and second leg segments and a base segment that extends in between and physically connects to the first and second leg segments. In some embodiments, the second gate electrode segments are positioned above the semiconductor layer structure in between the first and second legs of respective ones of the source regions when the semiconductor device is viewed from above. In some embodiments, the semiconductor layer structure further comprises a plurality of well contact regions that have the second conductivity type, each well contact region positioned within the base segment of a respective one of the source regions when the semiconductor device is viewed from above.

Pursuant to still further embodiments of the present invention, semiconductor devices are provided that comprise a semiconductor layer structure comprising a drift region having a first conductivity type, a source region having the first conductivity type and a well region having a second conductivity type between the drift region and the source region. The source region has a U-shape when the semiconductor device is viewed from above.

In some embodiments, the semiconductor layer structure further comprises a well contact region having the second conductivity type within the source region. In some embodiments, the combination of the source region and the well region has a U-shape when the semiconductor device is viewed from above, and the source region is formed within an upper portion of the well region.

In some embodiments, the source region has first and second leg segments and a base segment that extends in between and physically connects to the first and second leg segments when the semiconductor device is viewed from above, and the semiconductor layer structure further comprises a JFET region having the first conductivity type that is positioned in between first and second leg segments.

In some embodiments, the semiconductor device further comprises a monolithic gate electrode on an upper surface of the semiconductor layer structure, the monolithic gate electrode comprising a plurality of U-shaped openings when the semiconductor device is viewed from above.

In some embodiments, the source region is one of a plurality of source regions and the well region is one of a plurality of well regions, wherein each of the plurality of source regions has a U-shape when the semiconductor device is viewed from above. In some embodiments, the source regions arranged in rows and columns when the semiconductor device is viewed from above. In some embodiments, the semiconductor layer structure further comprises a plurality of well contact regions having the second conductivity type, where each well contact region is within a respective one of the source regions. In some embodiments, the well contact regions in a first of the columns of source regions have longitudinal axes that extend along a first axis, the well contact regions and portions of the source regions in which the well contact regions are positioned forming a first ohmic line that comprises a plurality of spaced-apart ohmic line segments.

In some embodiments, the semiconductor device further comprises a source metallization on an upper surface of the semiconductor layer structure, the source metallization contacting the semiconductor layer structure along the first ohmic line. In some embodiments, the semiconductor layer structure further comprises a plurality of first JFET regions having the first conductivity type that extend in a first direction in the semiconductor layer structure when the semiconductor device is viewed from above and a plurality of second JFET regions having the first conductivity type that extend in a second direction in the semiconductor layer structure when the semiconductor device is viewed from above, the first direction crossing the second direction. In some embodiments, the first direction is perpendicular to the second direction, and the first ohmic line extends in the first direction. In some embodiments, a first subset of the first JFET regions extend continuously in between respective pairs of adjacent spaced-apart ohmic line segments, while a second subset of first JFET regions each comprise a plurality of spaced-apart JFET region segments that extend in the first direction. In some embodiments, of the second JFET regions extend continuously in parallel to the first ohmic line.

Pursuant to additional embodiments of the present invention, semiconductor devices are provided that comprise a semiconductor layer structure comprising a drift region having the first conductivity type, a source region having the first conductivity type and a well region having a second conductivity type between the drift region and the source region. The drift region comprises a JFET region segment that extends along a first longitudinal axis, and the well region directly contacts at least three, but less than all, of a plurality of sidewalls of the JFET region segment.

In some embodiments, a channel region that is configured to be inverted during on-state operation of the semiconductor device is defined in the well region so that the channel region extends adjacent all of the at least three of the plurality of sidewalls of the JFET region segment. In some embodiments, the JFET region segment has a total of four sidewalls.

In some embodiments, the JFET region segment is part of a first JFET region that extends along the first longitudinal axis, the first JFET region comprising a plurality of JFET region segments. In some embodiments, the well region is one of a plurality of well regions, and wherein each of the well regions directly contacts at least three, but less than all, of a plurality of sidewalls of a respective one of the JFET region segments in the first JFET region.

In some embodiments, an upper portion of the well region has first and second well leg segments that extend in parallel to the first longitudinal axis and a well base segment that extends between and connects to first ends of the first and second well leg segments when the semiconductor device is viewed from above, and wherein the JFET region segment is positioned in between the first and second well legs when the semiconductor device is viewed from above. In some embodiments, the source region has first and second source leg segments that extend in parallel to the first longitudinal axis and a source base segment that extends between and connects to first ends of the first and second source leg segments when the semiconductor device is viewed from above, and wherein the source is within an upper portion of the well region. In some embodiments, the semiconductor layer structure further comprises a well contact region having the second conductivity type, wherein the well contact region extends through the source base segment to connect to the well region.

In some embodiments, the semiconductor device further comprises a source metallization that directly contacts the well contact region. In some embodiments, the source metallization comprises a silicide layer and a bulk metal layer on the silicide layer opposite the semiconductor layer structure, and wherein the silicide layer that directly contacts the first and second source leg segments. In some embodiments, a dielectric layer covers portions of the silicide layer that directly contact the first and second source leg segments so that the dielectric layer is in between the silicide layer and the source metallization.

In some embodiments, the semiconductor device further comprises a monolithic gate electrode on an upper surface of the semiconductor layer structure, the monolithic gate electrode comprising a plurality of U-shaped openings when the semiconductor device is viewed from above.

In some embodiments, the semiconductor device further comprises a monolithic gate electrode on an upper surface of the semiconductor layer structure, the monolithic gate electrode comprising a plurality of openings that are arranged in rows and columns when the semiconductor device is viewed from above.

Pursuant to yet additional embodiments of the present invention, semiconductor devices are provided that comprise a semiconductor layer structure, a gate electrode on the semiconductor layer structure, and a gate oxide layer interposed in between the gate electrode and the semiconductor layer structure. The gate electrode includes a plurality of U-shaped openings.

In some embodiments, the plurality of U-shaped openings are arranged in rows and columns when the semiconductor device is viewed from above. In some embodiments, the semiconductor layer structure comprising a drift region having the first conductivity type, a plurality of well regions having a second conductivity type, and a plurality of source regions having the first conductivity type, where the source regions are formed in upper portions of the respective well regions. In some embodiments, each source region has a U-shape when the semiconductor device is viewed from above. In some embodiments, the combination of each well region and a respective one of the source regions has a U-shape when the semiconductor device is viewed from above. In some embodiments, a U-shaped channel region is formed in an upper surface of each well region and extending around a perimeter of each well region when the semiconductor device is viewed from above.

Pursuant to still further embodiments of the present invention, semiconductor devices are provided that comprise a semiconductor layer structure, a gate electrode on the semiconductor layer structure, a gate oxide layer interposed in between the gate electrode and the semiconductor layer structure, an intermetal dielectric layer on the gate electrode, and a source metallization on the intermetal dielectric layer and the semiconductor layer structure. The gate electrode has a plurality of first openings that have a first size and a plurality of second openings that have a second size that is different than the first size.

In some embodiments, the semiconductor layer structure comprises a drift region having a first conductivity type, a plurality of sources region having the first conductivity type, a plurality of well regions having a second conductivity type between the drift region and the respective source regions, and a plurality of contact regions having the second conductivity type in upper portions of the respective well regions. In some embodiments, the first openings only expose upper portions of respective ones of the source regions. In some embodiments, the bulk source metallization layer comprises at least part of a source metallization, and the source metallization directly contacts the semiconductor layer structure through the second openings. In some embodiments, the bulk source metallization is separated from portions of the semiconductor layer structure that are exposed by the first openings by a dielectric layer. In some embodiments, the source metallization further comprises a silicide layer that directly contacts portions of the semiconductor layer structure that are exposed by the first openings.

In some embodiments, the contact regions are exposed through respective ones of the second openings.

In some embodiments, the second openings are arranged in a plurality of columns that extend in a second direction. In some embodiments, each first opening has a longitudinal axis that extends in a first direction that is different than the second direction.

In some embodiments, each well region extends below at least one of the first openings and at least one of the second openings when the semiconductor device is viewed from above.

Pursuant to still further embodiments of the present invention, semiconductor devices are provided that comprise a semiconductor layer structure comprising a source region having the first conductivity type, a silicide layer on the source region, and a dielectric layer on the silicide layer so that the silicide layer is in between and directly contacts both the source region and the dielectric layer.

In some embodiments, the semiconductor device further comprises a source metallization layer, wherein the dielectric layer is in between the silicide layer and the source metallization layer and directly contacts both the silicide layer and the source metallization layer.

In some embodiments, the silicide layer has a U-shape when the semiconductor device is viewed from above.

In some embodiments, the semiconductor layer structure further comprises a drift region having the first conductivity type and a plurality of well regions having a second conductivity type on the drift region, wherein the source region is one of a plurality of sources region having the first conductivity type, and the source regions are formed in upper portions of the respective well regions. In some embodiments, the semiconductor layer structure further comprises a plurality of contact regions having the second conductivity type that are formed in the upper portions the respective well regions. In some embodiments, the silicide layer directly contacts a first of the well contact regions. In some embodiments, each source region has a U-shape when the semiconductor device is viewed from above. In some embodiments, the combination of each well region and the source region that is formed in the upper portion of the well region has a U-shape when the semiconductor device is viewed from above

In some embodiments, the silicide layer is part of a source metallization, the source metallization further comprising a bulk source metallization layer, and wherein a dielectric layer is interposed between a portion of the bulk source metallization layer and the silicide layer.

Pursuant to still other embodiments of the present invention, semiconductor devices are provided that comprise a semiconductor layer structure comprising a drift region having the first conductivity type, a source region having the first conductivity type and a well region having a second conductivity type between the drift region and the source region. The drift region comprises a first JFET region that extends longitudinally along a first axis and a second JFET region segment that extends longitudinally along a second axis that is perpendicular to the first axis, the second JFET region segment extending from the first JFET region, and the well region surrounds the portions of the second JFET region that extend from the first JFET region when the semiconductor device is viewed from above.

In some embodiments, a channel region that is configured to be inverted during on-state operation of the semiconductor device is defined in the well region so that the channel region surrounds the portions of the second JFET region that extend from the first JFET region when the semiconductor device is viewed from above.

In some embodiments, the second JFET region segment is part of a second JFET region that extends along the second axis, the second JFET region comprising a plurality of JFET region segments.

In some embodiments, an upper portion of the well region has first and second well leg segments that extend in parallel to the first axis and a well base segment that extends between and connects to first ends of the first and second well leg segments when the semiconductor device is viewed from above, and wherein the second JFET region segment is positioned in between the first and second well legs when the semiconductor device is viewed from above.

### BRIEF DESCRIPTION OF THE DRAWINGS

FIG. 1A is a schematic plan view of a small portion of a conventional gate trench power MOSFET that includes trench shields with the upper metallization and dielectric layers omitted.

FIG. 1B is a cross-sectional view taken along line 1B-1B of FIG. 1A with the upper metallization and dielectric layers included.

FIG. 2A is a schematic plan view of a small portion of another conventional gate trench power MOSFET that includes both trench shields and support shields with the upper metallization and dielectric layers omitted.

FIG. 2B is a cross-sectional view taken along line 2B-2B of FIG. 2A with the upper metallization and dielectric layers included.

FIG. 3A is a schematic top view of a gate trench silicon carbide power MOSFET according to certain embodiments of the present invention and also shows the bond wires that can be used to connect the gate and source pads to external circuits.

FIG. 3B is a schematic top view of the power MOSFET of FIG. 3A with an upper protective layer omitted to show the full gate and source metallization.

FIG. 4A is a schematic perspective view of a small portion of a power MOSFET according to embodiments of the present invention that corresponds to the box labelled A in FIG. 3A.

FIG. 4B is a schematic top view of the power MOSFET of FIG. 4A with the upper dielectric layers and the source metallization omitted to show the gate electrodes and the upper surface of the semiconductor layer structure.

FIGS. 4C and 4D are cross-sectional views taken along lines 4C-4C and 4D-4D, respectively, of FIG. 4B with the upper dielectric layers and the source metallization that are omitted in FIG. 4B added for context.

FIG. 5A is a schematic perspective view of a small portion of a power MOSFET according to further embodiments of the present invention that corresponds to the box labelled A in FIG. 3A.

FIG. 5B is a schematic top view of the power MOSFET of FIG. 5A with the upper dielectric layers and the source metallization omitted to show the gate electrodes and the upper surface of the semiconductor layer structure.

FIGS. 5C and 5D are cross-sectional views taken along lines 5C-5C and 5D-5D, respectively, of FIG. 5B with the upper dielectric layers and the source metallization that are omitted in FIG. 5B added for context.

FIG. 6A is a schematic perspective view of a small portion of a power MOSFET according to embodiments of the present invention that corresponds to the box labelled A in FIG. 3A.

FIG. 6B is a schematic top view of the power MOSFET of FIG. 6A with the upper dielectric layers and the source metallization omitted to show the gate electrodes and the upper surface of the semiconductor layer structure.

FIGS. 6C and 6D are cross-sectional views taken along lines 6C-6C and 6D-6D, respectively, of FIG. 6B with the upper dielectric layers and the source metallization that are omitted in FIG. 6B added for context.

FIG. 7A is a schematic top view of a modified version of the power MOSFET of FIG. 6A with the upper dielectric layers and the source metallization omitted to show the gate electrodes and the upper surface of the semiconductor layer structure.

FIG. 7B is a cross-sectional view taken along line 7B-7B of FIG. 7A with the upper dielectric layers and the source metallization that are omitted in FIG. 7A added for context.

FIG. 8A is a schematic top view of yet another modified version of the power MOSFET of FIG. 6A with the upper dielectric layers and the source metallization omitted to show the gate electrodes and the upper surface of the semiconductor layer structure.

FIG. 8B is a cross-sectional view taken along line 8B-8B of FIG. 8A with the upper dielectric layers and the source metallization that are omitted in FIG. 8A added for context.

FIG. 9 is a schematic top view of still another modified version of the power MOSFET of FIG. 6A with the upper dielectric layers and the source metallization omitted to show the gate electrodes and the upper surface of the semiconductor layer structure.

FIG. 10 is a schematic top view of a modified version of the power MOSFET of FIGS. 4A-4D with the upper dielectric layers and the source metallization omitted.

FIG. 11A is a schematic top view of a small portion of a power MOSFET according to further embodiments of the present invention that has a planar gate design with the upper metallization and dielectric layers omitted.

FIG. 11B is a schematic perspective view of a small portion of the power MOSFET of FIG. 11A with the upper metallization and dielectric layers included for context.

FIG. 11C is a cross-sectional view taken along line 11C-11C of FIG. 11A with the upper metallization and dielectric layers added for context.

FIG. 12A is a schematic plan view of a small portion of a conventional planar gate power MOSFET with the gate electrodes, source metallization and upper dielectric layers omitted.

FIG. 12B is a schematic cross-sectional view taken along line 12B-12B of FIG. 12A with the gate electrodes, source metallization and dielectric layers added for context.

FIG. 13A is a schematic plan view of a power MOSFET according to further embodiments of the present invention with the source metallization and upper dielectric layers omitted.

FIGS. 13B and 13C are schematic cross-sectional views taken along lines 13B-13B and 13C-13C, respectively, of FIG. 13A with the source metallization and upper dielectric layers added for context.

FIG. 14A is a schematic plan view of a power MOSFET according to additional embodiments of the present invention with the source metallization and upper dielectric layers omitted.

FIGS. 14B and 14C are schematic cross-sectional views taken along lines 14B- 14B and 14C-14C, respectively, of FIG. 14A with the source metallization and upper dielectric layers added for context.

FIG. 15A is a schematic plan view of a semiconductor layer structure of a power MOSFET according to still further embodiments of the present invention.

FIGS. 15B and 15C are schematic cross-sectional views taken along line 15B-15B and 15C-15C, respectively, of FIG. 15A with the gate electrodes, source metallization and upper dielectric layers added for context.

FIG. 16A is a schematic plan view of a semiconductor layer structure of a power MOSFET according to additional embodiments of the present invention.

FIGS. 16B and 16C are schematic cross-sectional views taken along line 16B-16B and 16C-16C, respectively, of FIG. 16A with the gate electrodes, source metallization and upper dielectric layers of the power MOSFET added for context.

FIGS. 17A and 17B are plan views of the semiconductor layer structures of power MOSFETS that are modified versions of the power MOSFETS of FIGS. 15A-15C and FIGS. 16A-16C, respectively.

FIG. 18A is a schematic plan view of a semiconductor layer structure of a small portion of a conventional planar gate power MOSFET that has a hexagonal cell configuration with the gate electrodes, source metallization and upper dielectric layers omitted.

FIG. 18B is a schematic cross-sectional view taken along line 18B-18B of FIG. 18A with the gate electrodes, source metallization and upper dielectric layers added for context.

FIG. 19A is a schematic plan view of a semiconductor layer structure of a planar gate vertical power MOSFET according to additional embodiments of the present invention that has a hexagonal cell configuration with the gate electrodes, source metallization and upper dielectric layers omitted.

FIGS. 19B and 19C are schematic cross-sectional views taken along lines 19B-19B and 19C-19C, respectively, of FIG. 19A with the upper metallization and dielectric layers added for context.

FIG. 20 is a schematic plan view of the semiconductor layer structure of a modified version of the planar gate vertical power MOSFET of FIGS. 19A-19C.

Two-part reference numerals that include two numbers separated by a dash (-) are sometimes used in the figures and the discussion that follows to identify instances of multiple like elements. The full reference number may be used to refer to individual instances of the like element while the first part of the reference number may be used to refer to the like elements collectively.

It will be appreciated that the sizes (e.g., the thicknesses) of various regions in the drawings are not drawn to scale to allow enlargement of other regions of the drawings. For example, the substrates and drift regions of the power semiconductor devices shown in the drawings are depicted as being much thinner in the figures than they typically are in practice so that details of thinner upper layers and regions of the semiconductor devices can be more clearly depicted.

### DETAILED DESCRIPTION

The “pitch” of a semiconductor device having a unit cell structure refers to the center-to-center distance between adjacent unit cells. As the pitch is decreased (meaning the unit cells are packed closer together), the integration level of a semiconductor device increases, which is desirable. For gate-controlled semiconductor devices, the pitch may be defined as the center-to-center distance between adjacent gate electrodes. Vertical gate-controlled power semiconductor devices such as power MOSFETs and IGBTs that have a gate trench design have a smaller pitch than comparable planar gate-controlled vertical power semiconductor devices. The increased degree of integration provided by the reduced pitch lowers the on-state resistance per unit area. Moreover, vertical power semiconductor devices that have a gate trench design exhibit increased carrier mobility (2-4 times higher) than comparable planar gate vertical power semiconductor devices, which acts to further reduce the on-state resistance. However, as discussed above, gate trench power MOSFETs are susceptible to oxide reliability issues due to the presence of high electric fields in the gate oxide layers. Due to electric field crowding effects, the electric field levels in the lower “corners” of the gate oxide layer at the bottom edges of the gate trench may be particularly high (i.e., the portions of the gate oxide layers that cover the region where the sidewalls of the gate trenches merge into the bottoms of the respective gate trenches) during reverse blocking operation. Moreover, due to the difference in permittivity between silicon carbide and silicon oxide, the electric field in a silicon oxide gate oxide layer may be about 2.6 times higher than the electric field in the silicon carbide semiconductor layer structure adjacent the gate oxide layer.

So-called “trench shielding regions” (also called “bottom shields” or “trench shields”) are often provided underneath the gate trenches of gate trench power MOSFETs in order to reduce the electric field levels in the bottom portion of the gate oxide layer during reverse blocking operation. These trench shielding regions are formed by doping the portions of the semiconductor layer structure underneath the gate trenches with dopants having the same conductivity type as the dopants included in the channel regions of the device. The trench shielding regions are typically formed via one or more ion implantation processes in which p-type dopant ions (for an n-type MOSFET) are implanted through the bottom surfaces of the gate trenches. The trench shielding regions are electrically connected to the source terminal of the MOSFET by p-type trench shield connection patterns. While trench shielding regions can significantly reduce the electric field levels in the gate oxide layers, they also act to funnel the on-state currents through smaller regions (as the on-state currents flow around the p-type regions), thereby increasing the on-state resistance. Thus, there is an inherent trade-off between on-state resistance performance and device reliability in vertical gate trench power semiconductor devices.

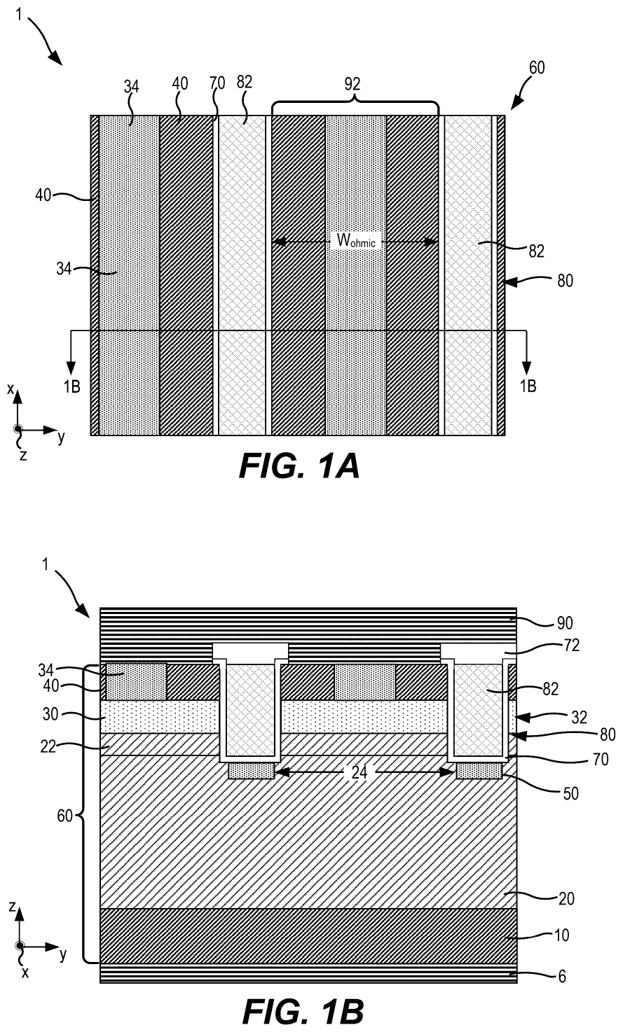

FIG. 1A is a schematic plan view of a small portion of a conventional gate trench power MOSFET that includes trench shielding regions. In FIG. 1A, the upper metallization and dielectric layers are omitted to show the upper surface of the semiconductor layer structure and the gate electrodes. FIG. 1B is a cross-sectional view taken along line 1B-1B of FIG. 1A with the upper metallization and dielectric layers added to provide context.

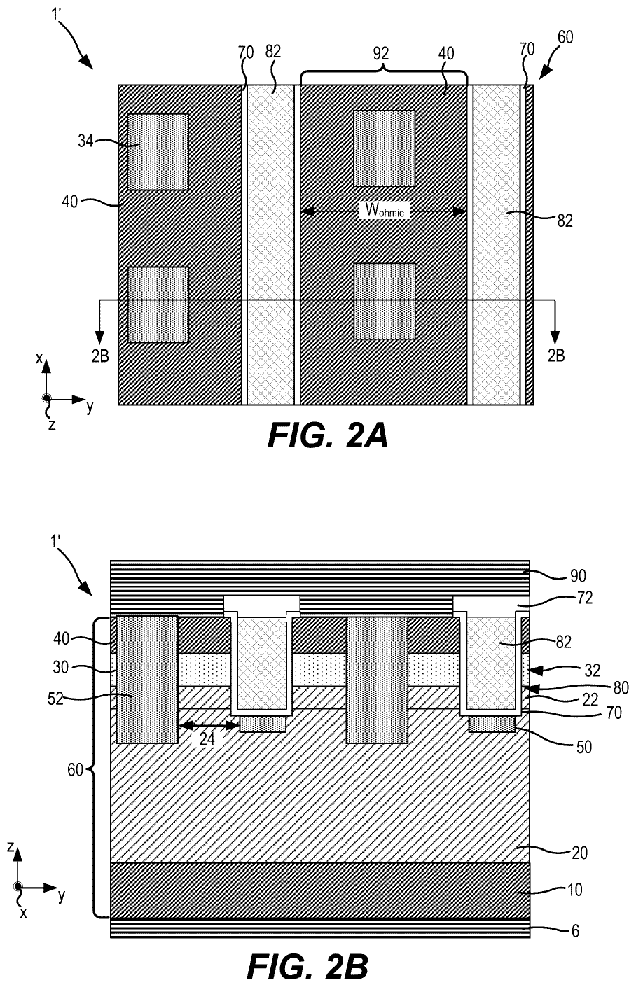

Referring first to FIG. 1A, power MOSFET 1 includes a wide bandgap semiconductor layer structure 60 that comprises a plurality of silicon carbide layers. The semiconductor layer structure 60 has first and second major surfaces that extend in the x-direction and the y-direction of an x-y-z coordinate system. The semiconductor layer structure 60 has a thickness in the z-direction, which is also referred to herein as the depth direction. The MOSFET 1 includes a large number of gate trenches 80 that are formed in the upper portion of the semiconductor layer structure 60. Only two gate trenches 80 are shown in FIGS. 1A-1B, as FIGS. 1A-1B only illustrates a small representative section of power MOSFET 1. Each gate trench 80 has a longitudinal axis that extends in the x-direction so that the gate trenches 80 extend in parallel to each other. A pair of heavily-doped (n⁺) n-type silicon carbide source regions 40 and a heavily-doped p-type well contact region 34 are formed in the upper surface of the semiconductor layer structure 60 between each pair of adjacent gate trenches 80. While two source regions 40 and a single well contact region 34 are provided between each pair of adjacent gate trenches 80 in FIGS. 1A-1B, it will be appreciated that other arrangements are possible. For example, in the device of FIGS. 2A-2B (discussed below), a single source region 40 and a plurality of well contact regions 34 that are spaced-apart from each other in the x-direction provided between each pair of adjacent gate trenches 80, with the well contact regions 34 formed as islands within the single source region 40.

Referring to FIG. 1B, the semiconductor layer structure 60 includes a thick heavily-doped n-type silicon carbide semiconductor substrate 10. A lightly-doped n-type (n⁻) silicon carbide drift region 20 (also referred to as a “drift layer”) is provided on the upper surface of the substrate 10. An upper portion of the drift region 20 may be more heavily doped than the remainder of the drift region 20, and this more highly-doped portion 22 of the drift region 20 is referred to herein as a JFET region 22 (which may be a continuous region or a plurality of discontinuous regions, as shown). A plurality of moderately-doped p-type wells 30 (also referred to as “p-wells”) are formed on the JFET region 22, typically by ion implantation. The well contact regions 34 and the source regions 40 are formed on upper portions of the p-wells 30, typically by ion implantation. The gate trenches 80 extend downwardly through upper portions of the semiconductor layer structure 60 into the drift region 20. Moderately-doped p-type trench shielding regions 50 are formed below each gate trench 80, and may extend underneath the respective gate trenches 80. A gate oxide layer 70 is formed conformally within each gate trench 80, and gate electrodes 82 are formed in the respective gate trenches 80 on the gate oxide layers 70. An intermetal dielectric pattern 72 covers the gate electrodes 82. A source metallization 90 is formed on the intermetal dielectric pattern 72 and on the n-type source regions 40 and the p-type well contact regions 34. A metal drain contact 6 is formed on the lower surface of the substrate 10.

A so-called “JFET gap 24 is defined in the semiconductor layer structure 60 between each pair of adjacent gate trenches 80. As used herein, the term “JFET gap” refers to the distance in the y-direction (i.e., a direction perpendicular to the longitudinal axes of the gate trenches and also perpendicular to the depth direction) between p-type shielding regions in the semiconductor layer structure such as the trench shielding regions 50 and support shields (see FIGS. 2A-2B). The on-state current flows through the JFET gaps 24 as the on-state current does not flow in the p-type shielding regions.

The source metallization 90 is typically designed to form an ohmic contact to both the n-type source regions 40 and the p-type well contact regions 34. Thus, the longitudinally-extending combination of the source region(s) 40 and the well contact region(s) 34 that are provided between a pair of adjacent gate trenches are sometimes referred to as an “ohmic line” 92 since the source metallization 90 makes ohmic contact with the source region(s) 40 and the well contact region(s) 34 in these regions of the device. Herein, the term “ohmic line” refers to the portion of the semiconductor layer structure that directly contacts the source metallization of a power MOSFET or IGBT. The source metallization 90 typically directly contacts the ohmic lines 92 so that on-state current can flow directly from the source metallization 90 into the source regions 40 and so that the well contact regions 34 may form ohmic contacts to the source metallization 90. The width W_{ohmic} of each ohmic line 92 (i.e., the extent of the ohmic line 92 in the y-direction) is related to the contact resistance and is selected based on the resistivities of the well contact regions 34 and the source regions 40. Photolithographic process limitations may also limit how small the width W_{ohmic} of the ohmic line 92 may be made. Thus, the requirements for the width W_{ohmic} of the ohmic line 92 may limit the cell pitch of the power MOSFET 1.

The width W_{ohmic} of the ohmic line 92 may be, for example, between 1.0-2.0 microns. The width of the JFET gap 24 that would optimize device performance, however, may be less the width W_{ohmic} of the ohmic line 92, but the contact resistance requirements and/or processing limitations may necessitate a larger JFET gap 24 than is optimal, resulting in an increased cell pitch. The expanded cell pitch increases the on-state resistance, and also negatively affects the reverse blocking capabilities of power MOSFET 1 due to the increased separation between adjacent gate trenches 80, since the increased distance between adjacent trench shielding regions 50 allows high electric fields to extend farther upwardly into the semiconductor layer structure 60 during reverse blocking operation. These higher electric field levels may deplete the well regions 30, allowing for punch through. Thus, the required width W_{ohmic} of the ohmic lines 92 may reduce device integration and also reduce the maximum blocking voltage of power MOSFET 1.

In order to increase the supportable reverse blocking voltage, many power MOSFET designs include so-called support shields that are provided in the JFET gaps between adjacent gate trenches. FIG. 2A is a schematic plan view of a small portion of a conventional gate trench power MOSFET 1′ that includes support shields 52. The upper metallization and dielectric layers are omitted in FIG. 2A. FIG. 2B is a cross-sectional view taken along line 2B-2B of FIG. 2A with the upper metallization and dielectric layers included.

As can be seen by comparing FIGS. 1A-1B to 2A-2B, power MOSFET 1′ is very similar to power MOSFET 1, except that power MOSFET 1′ includes moderately-doped p-type support shields 52 that extend downwardly from the well contact regions 34 in the middle of the JFET gaps 24. The p-type support shields 52 act to suppress the electric fields in the upper portion of the semiconductor layer structure 60 during reverse blocking operation, thereby lowering the electric fields in the gate oxide layers 70, which improves the reliability of power MOSFET 1′. Unfortunately, however, the addition of the support shields 52 increases the pitch of power MOSFET 1′, since the pitch must be increased to make room for the support shields 52. Thus, the provision of support shields 52 may be an imperfect solution to the above-discussed problems with MOSFET 1 of FIGS. 1A-1B.

Pursuant to embodiments of the present invention, power MOSFETs and other gate-controlled semiconductor devices are provided that may have improved trade-offs between on-state resistance performance and device reliability, and which may also exhibit improved short circuit switching behavior. The power semiconductor devices according to embodiments of the present invention may have ohmic lines that cross the gate electrodes (e.g., extend perpendicularly to the gate electrodes) as opposed to ohmic lines that extend in parallel to the gate electrodes. Since the ohmic lines do not extend in the x-direction in between the gate electrodes, the contact resistance is no longer a function of the width W_{ohmic}. Consequently, the cell pitch may be decreased (meaning the distance between adjacent gate electrodes is reduced). Since an aggressive cell pitch may be used, the need for support shields may be eliminated as the JFET gaps are already small. The reduced cell pitch lowers the on-state resistance per unit area since the number of unit cells is increased, and the small JFET gaps provide good shielding for the gate oxide layers and protect against punch-through during reverse blocking operation. The JFET gaps in power semiconductor devices according to embodiments of the present invention may, for example, be between 0.5-1.6 microns depending on the dose and implant energy of the ion implantation step used to form the trench shields.

Since the ohmic lines may extend perpendicularly to the gate trenches (meaning that a longitudinal axis of each ohmic line may cross longitudinal axes of the gate trenches at angles of 90°), the portions of the upper surface of the semiconductor layer structure that are between the gate trenches may be covered with a dielectric layer, even though such portions of the semiconductor layer structure are part of the active region of the device. During on-state operation, current may flow vertically (i.e., in the depth direction) from the source metallization into the ohmic lines, and may then flow generally horizontally into the source regions between adjacent gate trenches as well as flowing vertically through the source regions and the channel regions in the p-wells into the drift region of the device. Notably, this design increases the average length of the overall on-state current path. Increasing the on-state current path is non-intuitive, as longer current paths generally have higher resistance. Here, however, the current path is increased by routing the current to flow horizontally through the n-type source region, which is a highly-doped region that has a relatively low resistance. As such, the increase in the resistance caused by the increased current path may be less than the reduction in the resistance provided by the increased integration gained by the aggressive cell pitch. Moreover, in some embodiments, a silicide layer may be formed at the upper surface of the portions of the source regions that are in between adjacent gate trenches. Since a silicide layer may have a resistance that is orders of magnitude less than the resistance of the source region, much of the horizontally-flowing on-state current will flow through the silicide regions, and thus the impact of the horizontally-flowing on-state current on the on-state resistance may be negligible.

In some embodiments, the ohmic lines may be continuous ohmic lines and the gate trenches may be discontinuous gate trenches (since the ohmic lines interrupt the gate trenches). Such a design may be preferred in some cases as a continuous ohmic line has more surface area for the ohmic contact (and hence the width of the ohmic line may be reduced). An important parameter in the power semiconductor devices according to embodiments of the present invention is the separation between adjacent ohmic lines, as this will define the source resistance of the device. The source resistance can therefore readily be tuned by adjusting the pitch of the ohmic lines, and the devices can be designed to have a higher source resistance than is exhibited by conventional power semiconductor devices. The increased source resistance may improve the short circuit capabilities of the device, as will be explained in greater detail herein.

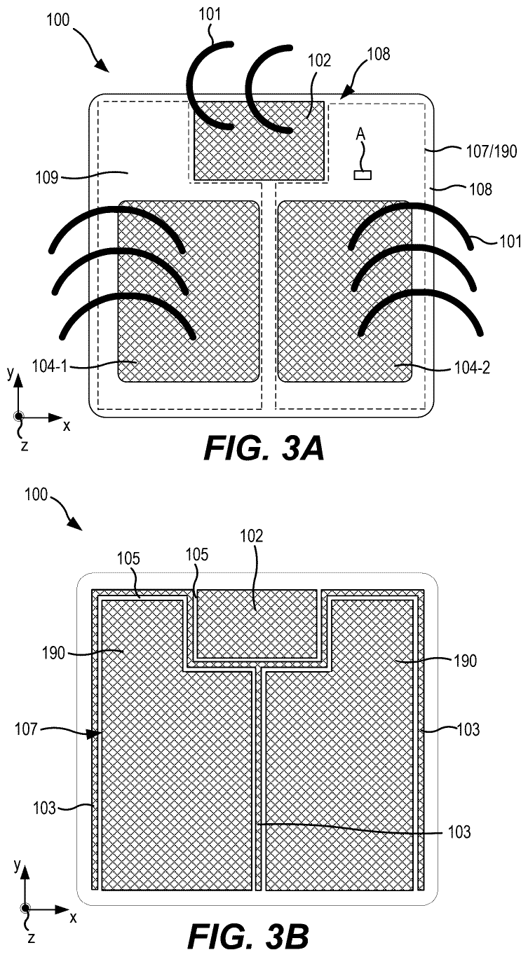

Embodiments of the present invention will now be described in more detail with reference to FIGS. 3A-20. It will be appreciated that features of the different embodiments disclosed herein may be combined in any way to provide many additional embodiments. Thus, it will be appreciated that various features of the present invention are described below with respect to specific examples, but that these features may be added to other embodiments and/or used in place of example features of other embodiments to provide many additional embodiments. Thus, the present invention should be understood to encompass these different combinations. Additionally, while the example embodiments focus on MOSFET implementations, it will be appreciated that the same techniques may be used in other gate trench power semiconductor devices such as insulated gate bipolar transistors (IGBTs), gate controlled thyristors and the like. It will also be appreciated that the term MOSFET is used broadly to encompass devices that use both oxide-based gate dielectric layers and non-oxide gate dielectric layers (e.g., nitrides, high dielectric constant materials, etc.), and that the gate electrodes of the MOSFETs may comprise any conductive material (including semiconductor materials) and is not limited to metal gate electrodes.

FIG. 3A is a schematic top view of a gate trench silicon carbide power MOSFET 100 according to certain embodiments of the present invention. FIG. 3B is a schematic plan view of the power MOSFET 100 with an upper protective layer omitted to show the full gate and source metallization. As will be discussed below, power MOSFET 100 includes a semiconductor layer structure 160 that comprises a plurality of semiconductor layers/regions. At least one of the semiconductor layers in the semiconductor layer structure 160 may be a silicon carbide layer. Various metal and/or dielectric layers are formed on either side of the semiconductor layer structure 160 and/or are formed in trenches in the semiconductor layer structure 160.

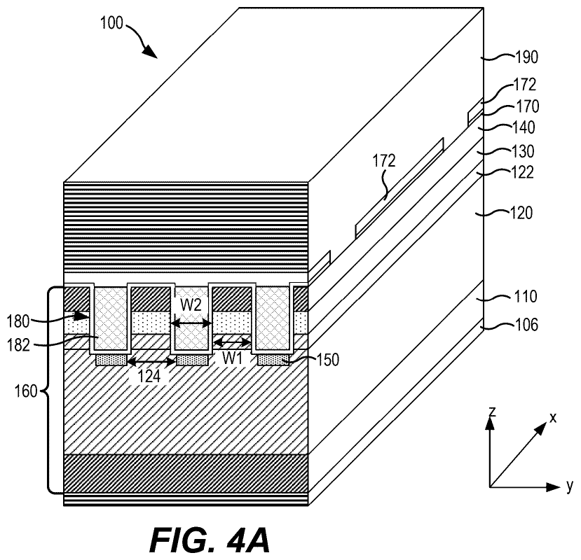

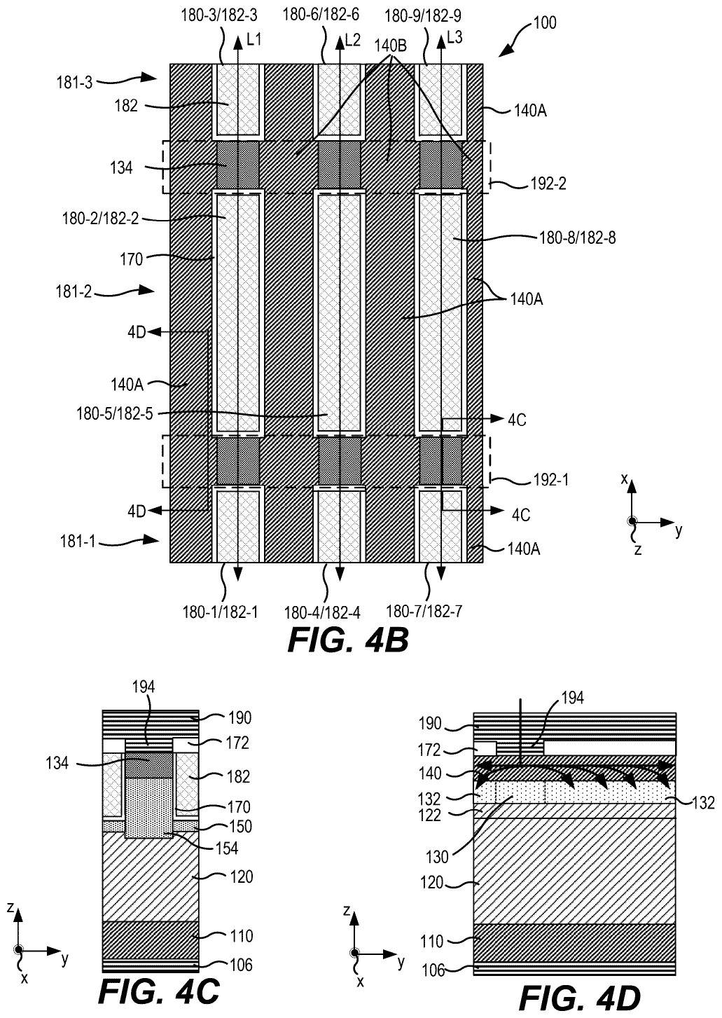

Referring to FIG. 3A, power MOSFET 100 includes a gate pad 102 and one or more source pads 104-1, 104-2 that are each formed on the upper side of the semiconductor layer structure 160 (the semiconductor layer structure 160 is shown in FIGS. 4A-4D). A metal drain pad 106 (see FIGS. 4A and 4C-4D) is provided on the bottom side of the semiconductor layer structure 160. The gate pad 102, the source pads 104 and the drain pad 106 form the respective gate, source and drain terminals of power MOSFET 100. The gate and source pads 102, 104 may each be formed of a metal, such as aluminum, that bond wires can be readily attached to via conventional techniques such as thermo-compression or soldering. The drain pad 106 may likewise be a metal pad. A protective layer 109 such as a polyimide layer may cover the entire upper surface of power MOSFET 100 except for the gate and source pads 102, 104.

Still referring to FIG. 3A, the power MOSFET 100 includes a source metallization 190 (indicated by the dashed boxes in FIG. 3A) that electrically connects certain regions of the semiconductor layer structure 160 to the source pads 104-1, 104-2. The source metallization 190 may include, for example, an ohmic contact layer (e.g., a metal silicide layer) that directly contacts the semiconductor layer structure 160, one or more optional adhesion and or barrier metal layers, and a bulk metal layer. Typically, the source pads 104 are a part of the bulk metal layer that is exposed through the protective layer 109. Herein, the source metallization 190 will be illustrated as a single layer for simplicity, but it will be appreciated that it typically includes multiple layers and may have any appropriate form. The source metallization 190 may generally overlie or correspond to an “active region” 107 of the power MOSFET 100 where the unit cell transistors are located. An inactive region 108 of power MOSFET 100 surrounds the active region 107. The inactive region 108 may include a termination region that extends around the periphery of the MOSFET 100 that includes guard rings, junction termination elements or other termination structures (not shown), a gate pad region that underlies the gate pad 102, and gate bus regions.

Bond wires 101 are shown in FIG. 3A that may be used to connect the gate pad 102 and the source pads 104 to external circuits or the like. The drain pad 106 on the bottom side of power MOSFET 100 may be connected to an external circuit through, for example, an underlying submount (not shown).

FIG. 3B is another plan view of power MOSFET 100 with the polymide layer 109 omitted to expose the full source and gate metallization. As shown in FIG. 3B, the source metallization 190 extends throughout the active region 107 of the device. The gate metallization includes the gate pad 102 and one or more gate buses 103. The source metallization 190 is spaced apart from both the gate pad 102 and the gate bus 103 so that a single metal layer may be used to form the source metallization and the gate metallization. The gate pad 102 is spaced apart from the gate bus 103 so that the gate current may pass through one or more lumped gate resistors (not visible in the figures) that are formed underneath an intermetal dielectric layer 105. The lumped gate resistors may, for example, improve the electromagnetic interference (“EMI”) performance of the device and/or improve the stability of long feedback loops that are created as the lengths of the gate electrodes are increased in order to increase the power handling capability of the device. The metal gate buses 103 extend around much of the periphery of the active region 107. The gate buses 103 may provide a low resistance path for distributing gate signals that are applied to the gate pad 102 to the gate electrodes 182 (discussed below) that extend throughout the active region 107.

FIGS. 4A-4D illustrate a small portion of power MOSFET 100 FIGS. 3A-3B. The small portion of power MOSFET 100 illustrated in FIGS. 4A-4D corresponds to the region labeled A in FIG. 3A. FIG. 4A is a schematic perspective view of the region A, while FIG. 4B is a schematic top view of the portion A with the upper dielectric layers and the source metallization omitted to show the gate electrodes and the upper surface of the semiconductor layer structure. FIGS. 4C and 4D are cross-sectional views taken along lines 4C-4C and 4D-4D, respectively, of FIG. 4B with the upper dielectric layers and the source metallization that are omitted in FIG. 4B added for context in FIGS. 4C-4D.

Referring to FIGS. 4A-4B, power MOSFET 100 includes an n-type silicon carbide semiconductor substrate 110. The substrate 110 may comprise, for example, a single crystal 4H silicon carbide semiconductor substrate that is heavily-doped with n-type impurities (i.e., an n+ silicon carbide substrate). The impurities may comprise, for example, nitrogen or phosphorous. In example embodiments, the n-type substrate 110 may have a doping concentration of, for example, between 1×10¹⁸ atoms/cm³ and 1×10²¹ atoms/cm³, although other doping concentrations may be used. The substrate 110 may be relatively thick in some embodiments (e.g., 20-100 microns or more). The substrate 110 may be partially or fully removed in some embodiments.

A lightly-doped n-type (n−) silicon carbide drift layer 120 is provided on an upper surface of the substrate 110. The drift layer 120 may also be referred to herein as a drift region 120. Typically, the drift layer 120 is formed via an epitaxial growth process on the silicon carbide substrate 110 and is doped during growth. The n-type drift region 120 may have, for example, a doping concentration of 1×10¹⁴ to 5×10¹⁷ dopants/cm³, with the doping level typically selected based on a blocking voltage rating of the device. The n-type drift region 120 may be a thick region, having a vertical height above the substrate 110 of, for example, 3-50 microns. A more heavily doped JFET region 122 is formed in the upper portion of the drift region 120. The JFET region 122 has a higher peak doping concentration than the remainder of the drift region 120. In example embodiments, the JFET region 122 may have a peak doping concentration that is between twice and ten times the peak doping concentration of the lower portion of the drift layer 120. The JFET region 122 is considered to be part of the drift layer 120, and has a higher doping concentration than the remainder of the drift region 120. The JFET region 122 may be a continuous region or a plurality of discontinuous regions, and may have a relatively constant doping concentration or a graded doping concentration. In example embodiments, the peak doping concentration of the JFET region 122 may be between 1×10¹⁶ dopants/cm³ and 5×10¹⁷ dopants/cm³. The JFET region 122 may have a thickness (i.e., extent in the depth direction) of, for example, between 0.3 and 1.0 microns.

A plurality of moderately-doped (p) p-type silicon carbide well regions 130 (which may also be referred to herein as a “p-wells 130”) are formed on the upper surface of the n-type drift region 120. The p-wells 130 may be formed, for example, via an ion implantation process. The p-wells 130 may, for example, have a peak doping concentration of between 6×10¹⁶ dopants/cm³ and 1×10¹⁹ dopants/cm³. The p-wells 130 may have a thickness (i.e., extent in the depth direction) of, for example, between 0.3 and 0.6 microns.

Heavily-doped n-type (n+) silicon carbide source regions 140 are formed on or in upper portions of the respective p-wells 130. Each source region 140 may extend, for example, to a maximum depth of between 0.2 microns and 1.0 microns from the upper surface of the semiconductor layer structure 160. The source regions 140 may, for example, have a peak doping concentration that exceeds 1×10²⁰ dopants/cm³. The heavily-doped n-type silicon carbide source regions 140 may be formed by ion implantation.

The substrate 110, the drift region 120 (including the JFET region 122), the p-wells 130 and the source regions 140 are all silicon carbide regions and are all part of the semiconductor layer structure 160 of power MOSFET 100. The semiconductor layer structure 160 further includes several additional silicon carbide regions, discussed below, including p-type well contact regions 134, p-type trench shielding regions 150 and p-type trench shield connection patterns 154. The drift layer 120 and the substrate 110 together act as a common drain region for the power MOSFET 100. The drain pad 106 is formed on the substrate 110 opposite the drift region 120.

A plurality of gate trenches 180 are formed in the upper portion of the semiconductor layer structure 160. Three gate trenches 180 are visible in FIG. 4A. A longitudinal axis of each gate trench 180 extends in the x-direction. Each gate trench 180 may, for example, extend to a maximum depth of between 0.5 microns and 1.5 microns from the upper surface of the semiconductor layer structure 160. The gate trenches 180 may be formed via an etching process.

A gate oxide layer 170 is provided in each gate trench 180 to cover the sidewalls and bottom surface of the gate trench 180. Each gate oxide layer 170 may comprise, for example, a silicon oxide (SiO₂) pattern. The gate oxide layers 170 may be formed generally conformally within the respective gate trenches 180.

A gate electrode 182 is formed in each gate trench 180 on the gate oxide layer 170. The gate electrodes 182 may comprise a conductive material such as a silicide (e.g., NiSi, TiSi, WSi, CoSi), a metal (e.g., Ti, Ta or W), a metal nitride (e.g., TiN, TaN or WN) or a doped semiconductor material (e.g., doped polycrystalline silicon). Most silicon carbide based power MOSFETs have doped polysilicon gate electrodes 182. The gate oxide layers 170 may insulate the gate electrodes 182 from the semiconductor layer structure 160, thereby preventing the gate electrodes 182 from short circuiting to the semiconductor layer structure 160. Each gate electrode 182 may connect to one of the gate buses 103 (see FIG. 3B). In the depicted embodiment, the gate electrodes 182 are recessed so that the upper surface of each gate electrode 182 is below an upper surface of the semiconductor layer structure 160. It will be appreciated that in other embodiments the gate electrodes 182 may extend above and onto the upper surface of the semiconductor layer structure 160, with the gate oxide layer 170 also extending onto the upper surface of the semiconductor layer structure 160 to insulate the gate electrodes 182 from the upper surface of the semiconductor layer structure 160. The gate electrodes 182 may be connected to the gate pad 102 through the gate buses 103.

Intermetal dielectric layers 172 are formed that cover each gate electrode 182. The intermetal dielectric layers 172 insulate the source metallization 190 from the gate electrodes 182. As will be discussed in further detail below, the intermetal dielectric layers 172 may also extend onto first portions 140A of the source region 140 that are in between pairs of adjacent gate trenches 180.

Moderately doped p-type trench shielding regions 150 are formed underneath each gate trench 180. Each trench shielding region 150 may extend the full length of each gate trench 180. In example embodiments, the p-type trench shielding regions 150 may have doping concentrations of between 1×10¹⁷ dopants/cm³ and 1×10¹⁹ dopants/cm³. The trench shielding regions 150 may, for example, be formed by ion implantation (typically into the bottoms of the gate trenches 180). The trench shielding regions 150 define JFET gaps 124. The width of the JFET gaps 124 may be set based on minimum gap required by the processing equipment and/or to optimize the on-state resistance based on the tradeoff between the resistance in the JFET gap region (which resistance increases as the JFET gap 124 is narrowed due to current crowding) and the number of unit cells per unit area (which number increases as the JFET gap 124 is reduced, and the larger number of unit cells acts to reduce the on-state resistance per unit area). In example embodiments, the width of the JFET gap 124 may be between 0.5-1.6 microns depending on the dose and implant energy of the ion implantation step used to form the trench shielding regions 150.

Referring to FIG. 4B, it can be seen that the source regions 140 extend as continuous stripes in the x-direction. A plurality of gate trenches 180 with the gate electrodes 182 therein extend in between each pair of adjacent source region 140 stripes. The gate trenches 180 that extend between a pair of adjacent source region 140 stripes may be aligned in the x-direction. As such, when viewed from above, power MOSFET 100 has gate trenches 180 (with gate electrodes 182 therein) that are arranged in rows and columns. In the view of FIG. 4B, the gate trenches 180 in one of the rows 181-2 of gate trenches 180 are completely visible in FIG. 4B, as are portions of the gate trenches 180 in two additional rows 181-1, 181-3.

As can also be seen in FIG. 4B, a plurality of ohmic lines 192 are defined in the upper surface of the semiconductor layer structure 160. As discussed above, the ohmic lines 192 are the portions of the semiconductor layer structure 160 that directly contact the source metallization 190. The ohmic lines 192 are formed in the regions between adjacent rows 181 of gate trenches 180. A longitudinal axis of each ohmic line 192 extends in the y-direction and thus the longitudinal axes of the ohmic lines 192 extend or “run” perpendicular to the longitudinal axes of the gate trenches 180 and the gate electrodes 182.

The source region 140 may be viewed as having first portions 140A and second portions 140B. The first portions 140A are the portions that are in the regions between the gate trenches 180, as shown in FIG. 4B. The second portions 140B are the portions of the source region 140 that are part of the ohmic line 192 (i.e., the portions that contact the source metallization 190). In addition to the second portions 140B of the source region 140, each ohmic line 192 also includes a plurality of heavily-doped p-type well contact regions 134.

The second portions 140B of the source region 140 provide a current path for the on-state current to flow from the source metallization 190 into the first portions 140A of the source region 140 so that the on-state current may flow into the channel regions 132. The well contact regions 134 provide a low resistance (e.g., ohmic) connection between the source metallization 190 and the p-wells 130. In the depicted embodiment, each ohmic line 192 comprises alternating sections of source region 140B and well contact regions 134. Embodiments of the present invention, however, are not limited thereto. For example, in other embodiments, the extent of the well contact regions 134 in the x-direction may be reduced so that each ohmic line 192 includes a single continuous second portion 140B of the source region 140 that has a plurality of well contact regions 134 formed therein that appear as “islands” in the second portion 140B of the source region 140 when the MOSFET 100 is viewed from above. As another example, the well-contact regions 134 need not be aligned with the gate trenches 180 as shown and/or the widths of the well-contact regions 134 in the y-direction can be varied to be less than or greater than the width of the gate trenches 180. The number of well contact regions 134 may also be varied.

As can best be seen in FIG. 4C, the source metallization 190 directly contacts the upper surface of the well contact region 134. The well contact region 134 extends the full length of the ohmic line 192 in the x-direction. As such, the well contact region 134 forms the end walls of the gate trenches on either side of the well contact region 134. A p-type trench shield connection pattern 154 is formed underneath each p-type well contact region 134. Each trench shield connection pattern 154 may directly contact one or more trench shielding regions 150 so as to electrically connect the trench shielding regions 150 to the source metallization 190 through the trench shield connection pattern 154 and the well contact region 134. As shown, the trench shield connection pattern 154 may extend deeper into the semiconductor layer structure than the trench shielding regions 150. This may advantageously route currents during an avalanche breakdown event to flow primarily through the trench shield connection patterns 154, which may help protect the gate oxide layers 170 that are adjacent channel regions 132 of the device from increased electrical fields during an avalanche breakdown event. The dashed boxes 192-1, 192-2 in FIG. 4B that illustrate the locations of the ohmic lines 192-1, 192-2 also show the extent of the trench shield connection patterns 154. The trench shield connection patterns 154 may both provide an electrical connection between the source metallization 190 and the trench shielding regions 150 and may also act akin to the support shields 52 included in power MOSFET 1′ as they will assist in lowering electric field levels in upper portions of the semiconductor layer structure 160 during reverse blocking operation.

As can be seen in both FIGS. 4A and 4D, the intermetal dielectric layer 172 covers the first portions 140A of the source region 140, which are the portions of the source region 140 that extend on top of the portions of the p-wells 130 that include p-type channel regions. Thus, while not shown in FIG. 4B (since dielectric layer 172 and source metallization 190 are omitted in FIG. 4B), the intermetal dielectric layer 172 extends in stripes in the x-direction to completely cover the upper surface of the active region except for the ohmic lines 192, which are disposed in between the stripes of intermetal dielectric layer 172. The source metallization 190 is formed on the upper surface of the semiconductor layer structure 160 (i.e., on the ohmic lines 192) and on the intermetal dielectric layer 172. The source metallization 190 may comprise at least a source contact (e.g., a metal silicide layer) that forms ohmic contacts with the semiconductor layer structure 160 and a bulk metallization layer on the source contact layer. Additional metal layers may be provided including, for example, one or more adhesion layers and/or one or more diffusion barrier layers.

As best shown in FIG. 4D, the portions of each p-well 130 that are adjacent a gate trench 180 act as channel regions 132 during on-state operation. In particular, when appropriate bias voltages are applied to the gate, drain and source terminals 102, 104, 106 of power MOSFET 100, a conductive n-type inversion layer is formed in the portion of each p-well 130 that is adjacent a gate electrode 182 (i.e., in the channel regions 132) will be inverted, allowing current to flow through the channel regions 132, Thus, a current path is created between the source and drain terminals 104, 106 that flows through the source metallization 190, the source regions 140, the channel regions 132, the drift region 120, the substrate 110 and the drain contact 106. The power MOSFET 100 may be turned off by changing the applied bias voltages (typically by lowering or removing the gate bias voltage). The portions of the p-wells 130 that are underneath the ohmic lines 192 will not have channel regions 132 formed therein during on-state operation as they are not next to gate electrodes 182.

Power MOSFET 100 of FIGS. 4A-4D varies in several significant aspects from power MOSFET 1 of FIGS. 1A-1B. First, as shown in FIGS. 4A and 4C-4D, the first portion of the source region 140A is covered by a dielectric layer 172 in the active region so that the source metallization 190 does not contact the first portion of the source region 140A.

Second, as can best be seen in FIG. 4B, the ohmic lines 192 have longitudinal axes that extend in a different direction than the longitudinal axes of the gate trenches 180, so that the longitudinal axes of the ohmic lines 192 cross the longitudinal axes of the gate trenches 180 when the MOSFET 100 is viewed from above. In the depicted embodiment, the longitudinal axes of the gate trenches 180 cross the longitudinal axes of the ohmic lines 192 at angles of 90° when the MOSFET 100 is viewed from above. In other words, the ohmic lines 192 extend perpendicularly to the gate trenches 180. Power MOSFET 1 includes ohmic lines 92, but in power MOSFET 1 the ohmic lines 92 run in parallel to the gate trenches 80 and the gate electrodes 82, with an ohmic line 92 provided between each pair of adjacent gate trenches 80.

Third, the gate trenches 180 and the gate electrodes 182 are much shorter in the longitudinal direction than the corresponding gate trenches 80 and gate electrodes 82 in power MOSFET 1. Because the gate trenches 180 and the gate electrodes 182 are shorter, in power MOSFET 100 multiple gate trenches 80 with gate electrodes 82 therein are aligned along common longitudinal axes. For example, as can be seen in FIG. 4B, three gate trenches 180-1, 180-2, 180-3 with respective gate electrodes 182 therein are aligned along a first longitudinal axis L1, three additional gate trenches 180-4, 180-5, 180-6 with respective gate electrodes 182 therein are aligned along a second longitudinal axis L2, and three more gate trenches 180-7, 180-8, 180-9 with respective gate electrodes 182 therein are aligned along a third longitudinal axis L3.

Fourth, as can best be seen in FIG. 1B, power MOSFET 1 includes p-type well contact regions 34 that are positioned between each pair of adjacent gate electrodes 82. While power MOSFET 100 includes corresponding p-type well contact regions 134, the p-type well contact regions 134 are part of ohmic lines 192 that extend perpendicular to the gate electrodes 182 in power MOSFET 100.

Fifth, in power MOSFET 1, the source metallization 90 directly contacts the entirety of the exposed upper surface of each source region 140 and each well contact region 34. In addition, in power MOSFET 1, the source metallization 90 directly contacts the portions of the source region 40 that are above the channel regions 32, allowing the on-state currents to flow vertically through the source regions 40 into the channels 32. In contrast, in power MOSFET 100, there may be significantly less direct contact between the source metallization 190 and the ohmic lines 192, and the upper surfaces of the first portions 140A of the source region 140 are covered by dielectric layer 172 so that the portions 140A do not directly contact the source metallization 190. Since the ohmic lines 192 are perpendicular to the gate electrodes 182 and are not provided between adjacent gate electrodes 182, the distance between adjacent gate electrodes 182 and hence the width of the JFET gap 124 can be reduced since the contact resistance is no longer a function of the width W_{ohmic}. As discussed above, this reduction in cell pitch acts to reduce the on-state resistance of power MOSFET 100 as compared to power MOSFET 1, since number of unit cells per unit area is increased. Moreover, the reduced width of the JFET gaps 124 may eliminate any need for support shields, since closely spaced trench shields 150 provide good shielding for the gate oxide layers 170 and protect against punch-through the p-wells 130 during reverse blocking operation.

In power MOSFET 100, the connections in the active region between the semiconductor layer structure 160 and the source metallization 190 are formed along the ohmic lines 192. In the embodiment of FIGS. 4A-4D, channels are not formed in any part of the ohmic lines 192. Thus, during on-state operation, current flowing in the source metallization 190 will not flow vertically through the ohmic line 192 into the drift region 120, but instead will flow in a horizontal direction out of the ohmic line 192 into the first portions 140A of the source region 140 that are in between the gate electrodes 182 on either side of the ohmic line 192. The direction of the current flow out of the ohmic lines 192 is shown in FIG. 4D.

As can best be seen from FIGS. 4B and 4D, on-state current will not flow downwardly through the ohmic line 192 because there is no gate electrode 182 adjacent the p-well 130 portion of the ohmic line 192 and hence this portion of the p-well 130 will not invert during on-state operation. As such, the on-state current that flows from the source metallization 190 into the portions 140B of the source region 140 will travel horizontally in the second portions 140B of the source regions 140B into the first portions 140A of the source region 140 that are on either side of the ohmic line 192. The channel regions 132 are underneath the first portions 140A of the source region 140. As the on-state current flows into the first portions 140A of the source region 140, some of the current will flow vertically through the source region 140 and the underlying channel region 132, while the remainder of the current will continue to flow horizontally through the first portion 140A of the source region 140 and only later turn to flow vertically through the source region 140 and the underlying channel region 132. The relative resistance of the current path determines how much and how far the current flows horizontally before turning to flow through the channel regions 132.

One unusual aspect of the design of power MOSFET 100 is that the average length of the on-state current path is increased since the on-state current must flow horizontally through the second portions 140B of the source region 140 to get from the source metallization 190 to the channel regions 132. Increasing the on-state current path is non-intuitive, as longer current paths generally have higher resistance. Here, however, the current path is increased by routing the current to flow horizontally through the source region 140, which is a highly-doped region that has a relatively low resistance. As such, the increase in the resistance caused by the increased current path may be less than the reduction in the resistance provided by the increased integration gained by the aggressive cell pitch. Moreover, as will be discussed below with reference to FIG. 10, in some embodiments, a silicide layer may be formed at the upper surface of the first portions 140A of the source regions 140 (i.e., the portions that are in between adjacent gate trenches 180). Since a silicide layer may have a resistance that is orders of magnitude less than the resistance of the source region 140, much of the horizontally-flowing on-state current will flow through the silicide regions, and thus the impact of the horizontally-flowing on-state current on the on-state resistance may be negligible.

Thus, the power MOSFETs according to embodiments of the present invention may have improved trade-offs between on-state resistance performance and device reliability.

In addition, power MOSFET 100 may also exhibit improved short circuit behavior. The “short circuit capability” of a power MOSFET refers to the time that the power MOSFET can operate at a specified temperature without damaging the device. Under so-called short circuit conditions the temperature of a power MOSFET may increase dramatically because of the large amount of power dissipated in the device when a high current passes through the device. The short circuit capability of a power MOSFET may be important because characteristics of the device and its packaging will determine the amount that the MOSFET heats up as a function of operating power. For example, if the power MOSFET conducts 500 amps at a voltage of 1200 volts, the power is 1200V*500 A=60 kilowatts. A power MOSFET with typical packaging may have a thermal impedance of, for example, 0.01° C./W. Thus, for such a MOSFET, operation at 60 kilowatts will heat the device up to about 600° C. (60 kilowatts*0.01° C./W=600° C.). Typically, a MOSFET may only sustain such temperatures without failing for a very short period of time such as, for example, 1 microsecond. In contrast, the same MOSFET might be able to operate at 200° C. for ten hours without failing.

In order to protect a MOSFET against such failure, a control circuit may be provided that senses when a short circuit condition is occurring and lowers the gate voltage (e.g., to 0 volts) in response thereto. The short circuit condition is not a normal operating condition and typically occurs because a larger system that includes the MOSFET is not operating as intended. The short circuit capability of a MOSFET is important, however, because when a short circuit condition occurs the control system must be able to shut off the gate voltage quickly to prevent failure of the device. The shorter the duration of the short circuit capability the faster the control circuit must be able to operate.

One way that the short circuit capability of a power MOSFET may be improved is by increasing the source resistance of the device, as the higher source resistance reduces the current during a short circuit event. Since the short circuit current will need to travel farther through the source region 140 during a short circuit event (since the current must travel horizontally through portions of the source region 140), the source resistance is increased and the short circuit capabilities are therefore improved. The amount of improvement may be tuned, for example, by modifying the spacing between adjacent ohmic lines 192.

Referring again to FIGS. 4A-4D, pursuant to some embodiments of the present invention, power semiconductor devices such as power MOSFET 100 are provided. These power semiconductor devices include a semiconductor layer structure 160 that comprises a drift region 120 having a first conductivity type (here, n-type), a first gate electrode 182 on the semiconductor layer structure 160 that extends along a first longitudinal axis L1, a second gate electrode 182 on the semiconductor layer structure 160 that extends along a second longitudinal axis L2, and a first ohmic line 192-1 that extends continuously in the semiconductor layer structure 160 along a first transverse axis T1. The first and second longitudinal axes L1, L2 cross the first transverse axis T1 when the semiconductor device 100 is viewed from above, as best shown in FIG. 4B.

The first and second gate electrodes 182-1, 182-2 are formed in respective gate trenches 180-1, 180-2. Consequently, the first and second gate electrodes 182-1, 182-2 are both on the semiconductor layer structure 160 and in the semiconductor layer structure 160. The first gate trench 180-1 and the second gate trench 180-2 each have a respective first end that is adjacent the first ohmic line 192-1. The power semiconductor device 100 further comprises a third gate electrode 182-3 that extends along a longitudinal axis in a third gate trench 180-3 in the semiconductor layer structure 160 and a fourth gate electrode 182-4 that extends along a longitudinal axis in a fourth gate trench 180-4 in the semiconductor layer structure 160, where the first longitudinal axis L1 is colinear with the longitudinal axis of the third gate electrode 182-3 and the second longitudinal axis L2 is colinear with the longitudinal axis of the fourth gate electrode 182-4. The first ohmic line 192-1 is in between the first gate trench 180-1 and the third gate trench 180-3 and is also in between the second gate trench 180-2 and the fourth gate trench 180-4 when the semiconductor device 100 is viewed from above.

The first longitudinal axis L1 extends in parallel to the second longitudinal axis L2, and the first transverse axis T1 crosses both the first longitudinal axis L1 and the second longitudinal axis L2 at angles of 90°. The power semiconductor device 100 further includes a dielectric layer 172 that extends continuously in a direction parallel to the first transverse axis T1 to cover the first gate electrode 182-1 and the second gate electrode 182-2 and an upper surface of the semiconductor layer structure 160 that is in between the first gate electrode 182-1 and the second gate electrode 182-2.

As best shown in FIG. 4B, the power semiconductor device 100 further comprises a second ohmic line 192-1 that extends continuously in the semiconductor layer structure 160 along a second transverse axis T2, where the first and second longitudinal axes L1, L2 cross the second transverse axis T2 when the semiconductor device 100 is viewed from above. The first transverse axis T1 extends in parallel to the second transverse axis T2. The first gate electrode 182-1 and the second gate electrode 182-2 are positioned between the first ohmic line 192-1 and the second ohmic line 192-2 when the semiconductor device 100 is viewed from above.

A first portion of the semiconductor layer structure 160 that is in between the first gate trench 180-1 and the second gate trench 180-2 comprises a drift region 120 having a first conductivity type (here, n-type), a source region 140 having the first conductivity type and a well region 130 having a second conductivity (here p-type) that is in between the drift region 120 and the source region 140. The first longitudinal axis L1 extends in a first direction (the x-direction), and the semiconductor device 100 is configured so that during on-state operation a source-drain current flows in the first direction (the x-direction, which is a horizontal direction) through the source region 140 in the first portion of the semiconductor layer structure 160.

While in FIG. 4A a width W1 of a portion of the semiconductor layer structure 160 that is in between the first gate trench 180-1 and the second gate trench 180-2 is shown to be slightly larger than a width W2 of the first gate trench 180-1, it will be appreciated that in other embodiments the width W1 may be less than the width W2.

Still referring to FIGS. 4A-4D, pursuant to further embodiments of the present invention, power semiconductor devices such as power MOSFET 100 are provided. These power semiconductor devices include a semiconductor layer structure 160 that comprises a drift region 120 having a first conductivity type (here, n-type), a source region 140 having the first conductivity type and a well region 130 having a second conductivity type (here, p-type) between the drift region 120 and the source region 140. The power MOSFET 100 further comprises a first gate electrode 182-1 on the semiconductor layer structure 160 that has a first longitudinal axis L1 that extends in a first direction (the x-direction), a second gate electrode 182-2 on the semiconductor layer structure 160 that has a second longitudinal axis L2 that extends in the first direction (the x-direction), and a dielectric layer 172 that extends continuously on the semiconductor layer structure 160 in a second direction (the y-direction), where the dielectric layer 172 crosses the first gate electrode 182-1, the second gate electrode 182-2 and a first portion 140A of the source region 140 that is in between the first gate electrode 180-1 and the second gate electrode 180-2. The dielectric layer 172 may directly contact the first portion 140A of the source region 140.

Continuing to refer to FIGS. 4A-4D, pursuant to still further embodiments of the present invention, power semiconductor devices such as power MOSFET 100 are provided. These power semiconductor devices include a semiconductor layer structure 160 that comprises a drift region 120 having a first conductivity type (here, n-type), a source region 140 having the first conductivity type and a well region 130 having a second conductivity type (here, p-type) between the drift region 120 and the source region 140. The power MOSFET 100 further comprises a first gate electrode 182-1 on the semiconductor layer structure 160 that has a first longitudinal axis L1 that extends in a first direction (the x-direction), a second gate electrode on the semiconductor layer structure 160 that has a second longitudinal axis L2 that extends in the first direction, the second gate electrode 182-2 adjacent the first gate electrode 182-1 in a second direction (the y-direction) that is perpendicular to the first direction, and a source metallization 190 on an upper surface of the semiconductor layer structure 160, where the source metallization 190 has a plurality of downwardly-extending protrusions 194 that directly contact an upper surface of the semiconductor layer structure 160, where the downwardly-extending protrusions 194 have respective longitudinal axes that extend in the second direction.

Continuing to refer to FIGS. 4A-4D, it can be seen that power MOSFET 100 comprises a semiconductor layer structure 160 that comprises a drift region 120 having a first conductivity type (here, n-type), a source region 140 having the first conductivity type and a well region 130 having a second conductivity type (here, p-type) between the drift region 120 and the source region 140. The power MOSFET 100 further comprises a first gate trench 180-1 in the semiconductor layer structure 160 that has a first longitudinal axis L1 that extends in a first direction (the x-direction), a second gate trench 180-2 in the semiconductor layer structure 160 that has a second longitudinal axis L2 that extends in the first direction, a first ohmic line 192-1 in the semiconductor layer structure 160 that has a third longitudinal axis that extends in a second direction (the y-direction), and a second ohmic line 192-2 in the semiconductor layer structure 160 that has a fourth longitudinal axis that extends in the second direction. A portion of the source region 140 that is within a first region that is in between the first gate trench 180-1, the second gate trench 180-2, the first ohmic line 192-1 and the second ohmic line 192-2 when the semiconductor device 100 is viewed in plan view completely covers a portion of the well region 130 that is within the first region. A dielectric layer 172 completely covers an upper surface of the first region.

As shown in FIG. 4D, the power MOSFET 100 is configured so that during on-state operation a source-drain current flows in the first direction through a first portion of the source region that is in between the first gate electrode 182-1 and the second gate electrode 182-2.

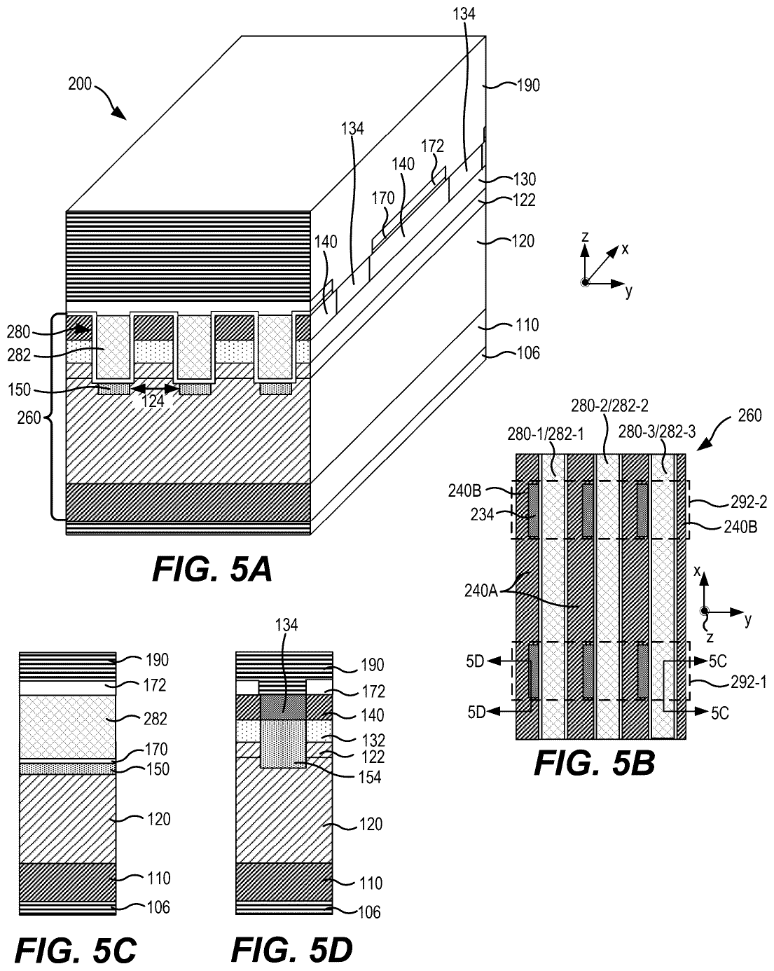

FIGS. 4A-4B depict one example power MOSFET 100 according to embodiments of the present invention. It will be appreciated that numerous modifications may be made thereto. FIGS. 5A-10 illustrate various additional example embodiments of power MOSFETs according to embodiments of the present invention that are modified versions of power MOSFET 100.

FIGS. 5A-5D illustrate a power MOSFET 200 according to further embodiments of the present invention. At the device level, power MOSFET 200 may appear the same as power MOSFET 100, and hence FIGS. 3A-3B accurately depict power MOSFET 200. FIGS. 5A-5D are various view of a small portion of power MOSFET 200 that corresponds to the box labelled A in FIG. 3A that illustrate the unit cell design of power MOSFET 200. In particular, FIG. 5A is a schematic perspective view of the small portion of MOSFET 200 and FIG. 5B is a schematic top view of the small portion of power MOSFET 200 with the upper dielectric layers and the source metallization omitted to show the gate electrodes and the upper surface of the semiconductor layer structure 260. FIGS. 5C and 5D are cross-sectional views taken along lines 5C-5C and 5D-5D, respectively, of FIG. 5B with the upper dielectric layers and the source metallization that are omitted in FIG. 5B added for context.

As can be seen by comparing FIGS. 5A-5D to FIGS. 4A-4D, power MOSFET 200 primarily differs from power MOSFET 100 in that power MOSFET 200 has gate trenches 280 and gate electrodes 282 that extend continuously along respective longitudinal axes and discontinuous ohmic lines 292 that extend perpendicular to the gate trenches/gate electrodes 280, 282, whereas power MOSFET 100 has discontinuous gate trenches 180 and gate electrodes 182 and continuous ohmic lines 192 that extend perpendicular to the gate trenches/gate electrodes 180, 182. Additionally, as shown best in FIG. 5B, in power MOSFET 200, the well contact regions 234 are positioned adjacent sidewalls of the respective gate trenches 280, and the extent of the ohmic lines 292 in the x-direction is increased to provide a similar contact area between the ohmic line 292 and the source metallization 290 that is provided in power MOSFET 100 between the ohmic lines 192 and the source metallization 190. Otherwise, power MOSFET 200 may be identical to power MOSFET 100, and hence further description of power MOSFET 200 will be omitted here.

Power MOSFET 200 will operate in the same manner, discussed above, as power MOSFET 100, with the on-state current passing from the source metallization 190 to the second portions 240B of the source region 240 that are part of the ohmic lines 292, and then flowing horizontally through the first portions 240A of the source regions 240 before turning to flow vertically through the channel regions 132.

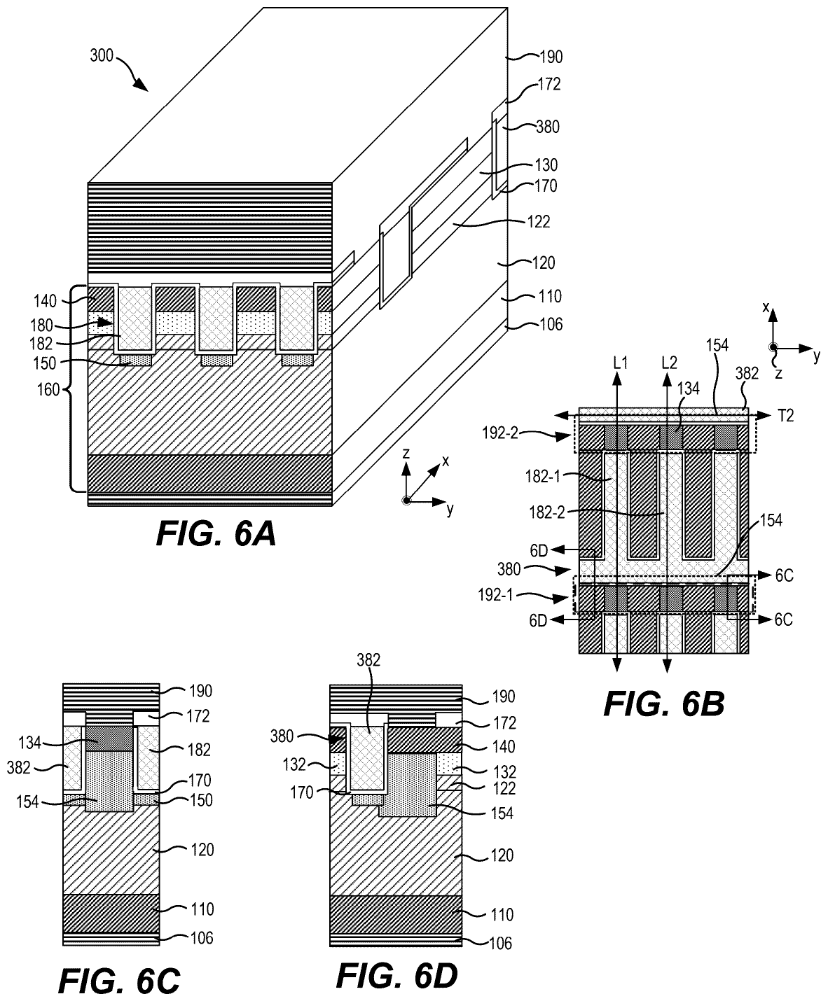

FIGS. 6A-6D illustrate a power MOSFET 300 according to further embodiments of the present invention. Power MOSFET 300 is similar to power MOSFET 100, but further includes a plurality of supplemental gate trenches 380 that extend perpendicularly to the gate trenches 180. FIGS. 3A-3B again accurately depict power MOSFET 300, and FIGS. 6A-6D are views illustrating the small portion of power MOSFET 300 that corresponds to the box labelled A in FIG. 3A. In particular, FIG. 6A is a schematic perspective view of the small portion of MOSFET 300 and FIG. 6B is a schematic top view of the small portion of power MOSFET 300 with the upper dielectric layers and the source metallization are omitted. FIGS. 6C and 6D are cross-sectional views taken along lines 6C-6C and 6D-6D, respectively, of FIG. 6B with the upper dielectric layers and the source metallization shown for context.

As can be seen by comparing FIGS. 6A-6D to FIGS. 4A-4D, power MOSFET 300 differs from power MOSFET 100 in that power MOSFET 300 further includes a plurality of supplemental gate trenches 380 that extend perpendicularly to the gate trenches 180. The provision of the supplemental gate trenches 380 along with the supplemental gate electrodes 382 formed therein converts the gate electrode structure of power MOSFET 100 in which the gate electrodes 182 only extend in one direction (the x-direction) into a gate electrode mesh that has gate electrodes 182, 382 that extend in two different directions. The provision of a gate electrode mesh may reduce the amount of gate runner that need be provided as the gate signal may be distributed through the gate electrode mesh. Each supplemental gate trench 380 may run directly next to a respective one of the ohmic lines 192.

As can be seen in FIG. 6C, the trench shielding region 150 is formed underneath both the gate trenches 180 and the supplemental gate trenches 380. As can be seen in FIG. 6D, a channel region 132 is provided on the left side of each supplemental gate trench 380. In addition, a high energy p-type ion implantation is performed on the right side of each supplemental gate trench 380, as can be seen in FIG. 6D, that forms a p-type trench shield connection pattern 154 to the right of each supplemental gate trench 384. A trench shield connection pattern 154 may extend longitudinally underneath each ohmic line 192 and may be electrically connected to the source metallization through the well contact regions 134.

Referring to FIGS. 6A-6D, pursuant to further embodiments of the present invention, power semiconductor devices such as power MOSFET 300 are provided that comprise a semiconductor layer structure 160 that comprises a drift region 120 having a first conductivity type (here, n-type), a first gate electrode 182 on the semiconductor layer structure 160 that extends along a first longitudinal axis L1, a second gate electrode 182 on the semiconductor layer structure 160 that extends along a second longitudinal axis L2, and a first ohmic line 192-1 that extends continuously in the semiconductor layer structure 160 along a first transverse axis T1. Power MOSFET further comprises a supplemental gate electrode 382 that extends in a first supplemental gate trench 380 in the semiconductor layer structure 160, the supplemental gate electrode 382 having a longitudinal axis T2 that is perpendicular to the first and second longitudinal axes L1, L2. A first end of the first gate electrode 182-1 contacts the supplemental gate electrode 382 and a first end of the second gate electrode 182-2 similarly contacts the supplemental gate electrode 382. The longitudinal axis T2 of the supplemental gate electrode 382 extends in parallel to the first transverse axis T1. The semiconductor layer structure 160 comprises a drift region 120 having a first conductivity type (here, n-type), a source region 140 having the first conductivity type, a well region 130 having a second conductivity (here, p-type) that is in between the drift region 120 and the source region 140, and a trench shielding region 150 having the second conductivity type that extends underneath the first gate trench 180-1, the second gate trench 180-2 and the supplemental gate trench 380. The semiconductor layer structure 160 further comprises a trench shield connection pattern 154 having the second conductivity type that extends along a sidewall of the supplemental gate trench 380.

Power MOSFET 300 may operate in the same fashion as power MOSFET 100, except that the gate signal is distributed throughout the gate mesh in power MOSFET 300. In addition, the trench shield connection pattern 154 in power MOSFET 300 extends further in the x-direction (i.e., is wider), as it partly extends underneath the supplemental gate trench 380. The wider trench shield connection pattern 154 in power MOSFET 300 may provide improved electric field suppression during reverse blocking operation as compared to power MOSFET 100.

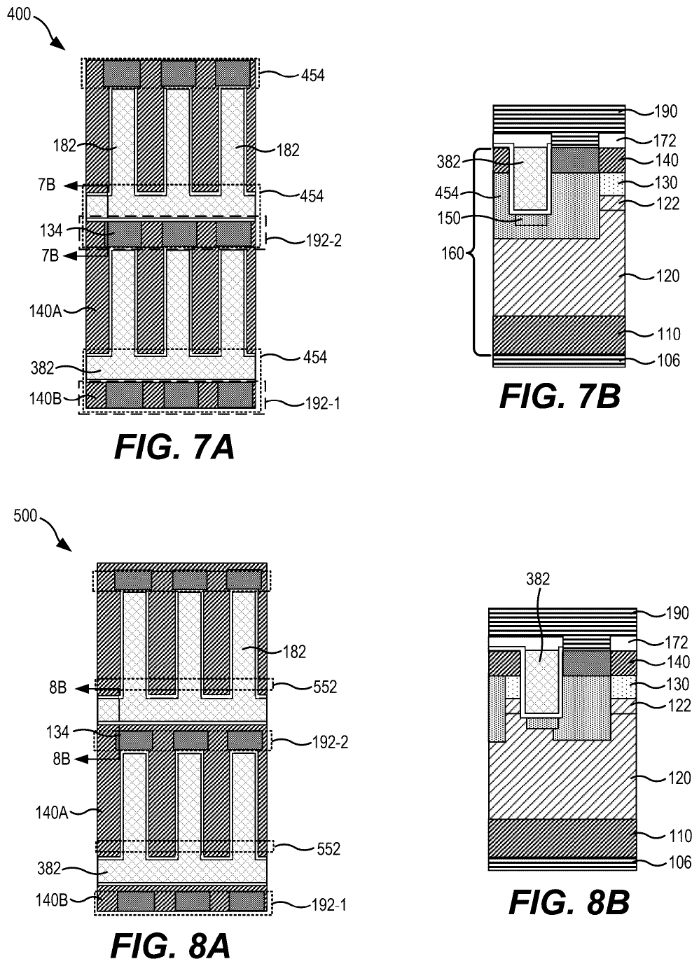

FIGS. 7A-7B illustrate a power MOSFET 400 according to further embodiments of the present invention that is a slightly modified version of power MOSFET 300. In particular, FIG. 7A is a schematic top view of a small portion of power MOSFET 400 with the upper dielectric layers and the source metallization omitted while FIG. 7B is a cross-sectional view taken along lines 7B-7B of FIG. 7A with the upper dielectric layers and the source metallization shown for context.

As can be seen by comparing FIGS. 7A-7B to FIGS. 6A-6B, power MOSFET 400 differs from power MOSFET 300 in that the trench shield connection pattern 454 in power MOSFET 400 is formed on each side of each supplemental gate trench 380. This design decreases the total channel area (since the channel region 132 that is provided on the left side of each supplemental gate trench 380 in power MOSFET 300 is no longer present), but may have improved reverse blocking characteristics due to the expanded trench shield connection pattern 454 in power MOSFET 400 which, as discussed above, also acts as a support shield.

FIGS. 8A-8B illustrate a power MOSFET 500 according to further embodiments of the present invention that is a slightly modified version of power MOSFET 300. In particular, FIG. 8A is a schematic top view of a small portion of power MOSFET 500 with the upper dielectric layers and the source metallization omitted while FIG. 8B is a cross-sectional view taken along lines 8B-8B of FIG. 8A with the upper dielectric layers and the source metallization shown for context.

As shown in FIG. 8A, power MOSFET 500 includes both trench shield connection patterns 154 as well as separate support shields 552. The trench shield connection patterns 154 are provided on a first side of the supplemental gate trenches 380 and the support shields 552 are provided on the other side of the supplemental gate trenches 380. As can best be seen by comparing FIGS. 6B and 8A, each second support shield 552 eliminates some of the channel area in power MOSFET 500 so that power MOSFET 500 has less channel area than power MOSFET 300. However, each second support shield 552 is spaced apart from its associated supplemental gate trench 380 so that some of eliminated channel area is regained by forming spaced apart channel regions along one side of each supplemental gate trench 380. The provision of the second support shields 552 may improve the reverse blocking performance of power MOSFET 500.

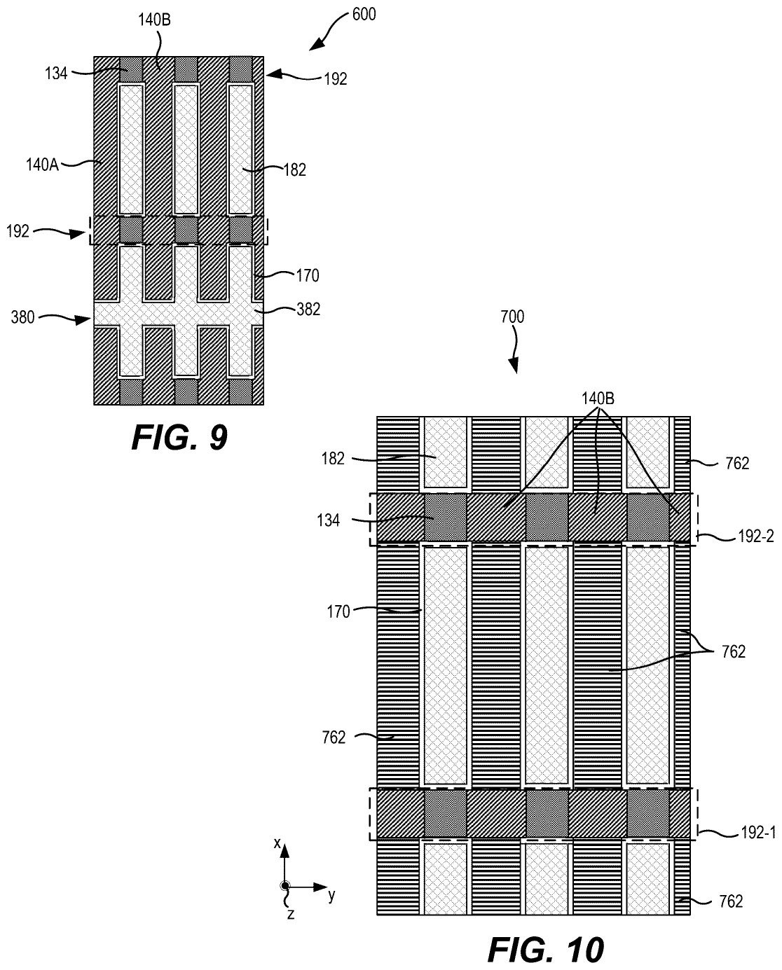

FIG. 9 is a schematic top view of a power MOSFET 600 that is yet another modified version of the power MOSFET 300 of FIG. 6A. Once again, in FIG. 9 the upper dielectric layers and the source metallization are omitted to show the gate electrodes and the upper surface of the semiconductor layer structure.

As can be seen by comparing FIGS. 6B and 9, power MOSFET 600 differs from power MOSFET 300 in that the supplemental gate trenches 380 are spaced apart from the ohmic lines 192. The embodiment of FIG. 9 illustrates that the number and positioning of the ohmic lines 192 may be selected independently of the number and positioning of the supplemental gate trenches 380.

FIG. 10 is a schematic top view of a power MOSFET 700 that is a modified version of the power MOSFET 100 of FIGS. 4A-4D. The view of FIG. 10 corresponds to the view of FIG. 4B, except that in FIG. 10 a silicide layer 762 is shown that is formed on the upper surface of the semiconductor layer structure 160.

As shown in FIG. 10, power MOSFET 700 may be identical to power MOSFET 100, except that power MOSFET 700 further includes the silicide layer 762. The silicide layer 762 may be formed to cover the entirety of the first portion 140A of the source region 140. As discussed above, the first portion 140A of the source region 140 is the port that is not part of the ohmic lines 192. While not shown in FIG. 10, the dielectric layer 172 may completely cover the silicide layer 762 so that the lower surface of the silicide layer 762 directly contacts the upper surface of the first portions 140A of the source region 140 while the upper surface of the silicide layer 762 directly contacts the intermetal dielectric layer 172. In other words, the dielectric layer 172 of FIGS. 4A and 4C-4D is also provided in FIG. 10, although it is not shown in FIG. 10 in order to show the silicide layer 762.

As described above with reference to FIG. 4D, some of the on-state current travels horizontally through the first portions 140A of the source region 140 before the on-state current transitions to flow vertically through the channel regions 132. This horizontal current flow occurs because the dielectric layer 172 covers the first portions 140A of the source region 140 so that current can only flow throughout the first portions 140A of the source region 140 through such horizontal current flow. The current flows horizontally because the resistance of the source region 140 is much lower than the resistance of the p-wells 130, and hence the current will tend to spread through the first portions 140A of the source region 140 before flowing downwardly through the channel regions 132. As noted above, this horizontal current flow increases the length of the on-state current path, and the increased path length increases the on-state resistance. By providing the silicide layer 762, much of the horizontal current flow will occur in the silicide layer 762 rather than in the source region 140. As the silicide layer 762 has a very low resistance (orders of magnitude lower than the source region 140), the increase in on-state resistance caused by the increased length of the current path can be made de minimis.

It should be noted that a silicide layer (not shown) will typically also be formed that covers the ohmic lines 192 when the source metallization 190 is formed to contact the ohmic lines 192. This silicide layer is not depicted in FIG. 10 to highlight the silicide layer 762 that is formed underneath the dielectric layer 172 to facilitate low-resistance horizontal current flow in power MOSFET 700.

Thus, referring to refer to FIGS. 4A, 4C-4D and 10, pursuant to still further embodiments of the present invention, power semiconductor devices such as power MOSFET 700 are provided. These power semiconductor devices include a semiconductor layer structure 160 that comprises a source region 140 having a first conductivity type (here, n-type). A silicide layer 762 is formed on the source region 140, and a dielectric layer 172 is formed on the silicide layer 762 so that the silicide layer 762 directly contacts both the source region 140 and the dielectric layer 172.

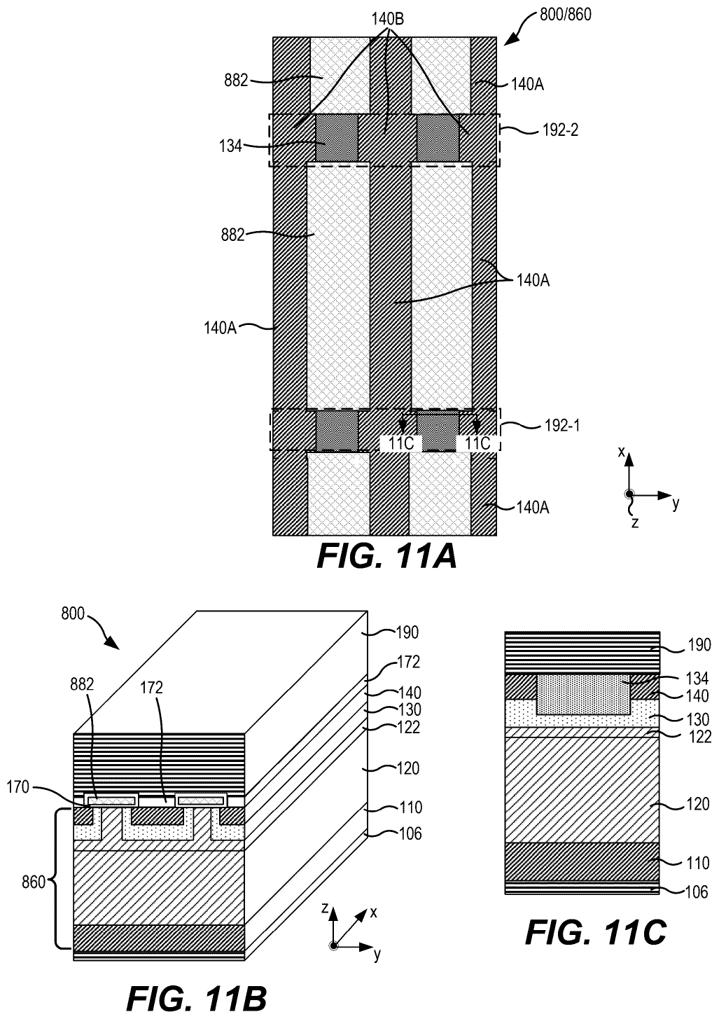

The above-discussed embodiments of the present invention are all vertical power MOSFETs having trench gates. It will be appreciated, however, that embodiments of the present invention are not limited thereto. For example, FIGS. 11A-11C illustrate a vertical power MOSFET 800 according to further embodiments of the present invention that has a planar gate design. In particular, FIG. 11A is a schematic top view of a small portion of power MOSFET 800 with the upper metallization and dielectric layers omitted, while FIG. 11B is a schematic perspective view of the portion of power MOSFET 800 in the region B of FIG. 11A with the upper metallization and dielectric layers added for context. FIG. 11C is a cross-sectional view taken along line 11C-11C of FIG. 11A with the upper metallization and dielectric layers added for context

As can be seen by comparing FIGS. 11A-11C to FIGS. 4A-4D, power MOSFET 800 is very similar to power MOSFET 100, with the primary difference being that power MOSFET 100 has gate electrodes 182 that are formed in gate trenches 180 within the semiconductor layer structure 160 while power MOSFET 800 has gate electrodes 882 that are formed on the uppermost surface of the semiconductor layer structure 860 (with a gate oxide layer insulating the gate electrodes from the semiconductor layer structure 860). Power MOSFET 800 is typically referred to as a “planar gate” vertical power MOSFET.

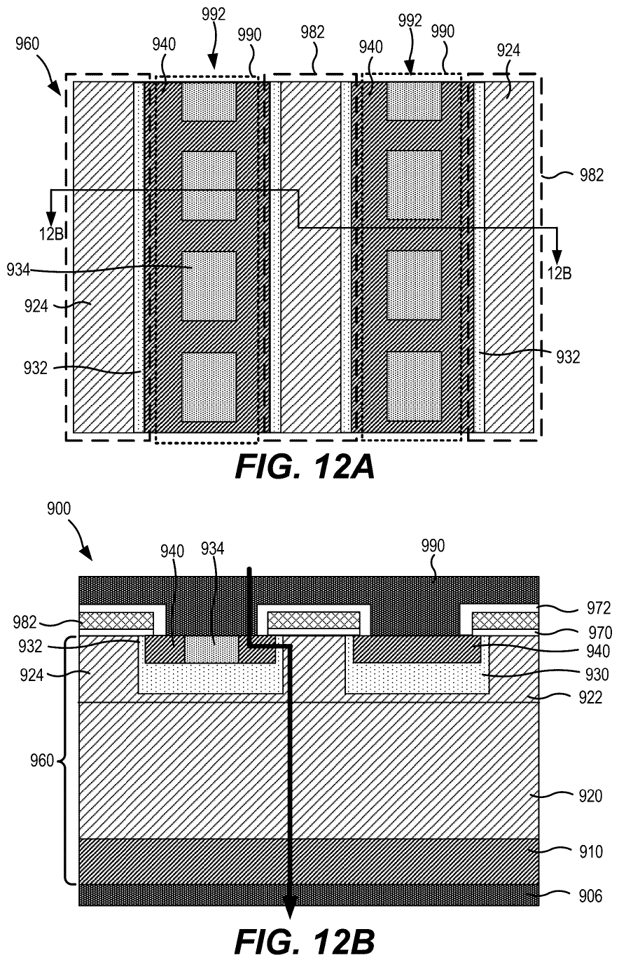

To understand how power MOSFET 800 of FIGS. 11A-11C provides improved performance, it is helpful to first briefly discuss the design of a conventional planar gate vertical power MOSFET. FIG. 12A is a schematic plan view of a semiconductor layer structure 960 of a conventional planar gate power MOSFET 900. The locations of the gate electrodes and source metallization that are formed on the upper surface of the semiconductor layer structure are shown in FIG. 12A using dashed lines (for the gate electrodes) and dotted lines (which indicate the locations where the source metallization directly contacts the semiconductor layer structure 960). FIG. 12B is a schematic cross-sectional view taken along line 12B-12B of FIG. 12A with the gate electrodes, source metallization and upper dielectric layers that are formed above the semiconductor layer structure 960 added in FIG. 12B to provide context.

As shown in FIGS. 12A-12B, power MOSFET 900 includes a heavily-doped n-type (n+) silicon carbide semiconductor substrate 910. A lightly-doped n-type (n⁻) silicon carbide drift region 920 is provided on the upper surface of the substrate 920. An upper portion 922 of the drift region 920 may have a higher doping concentration of n-type dopants than the lower portion of the drift region 920 and this upper portion may be referred to as a current spreading layer herein. Moderately-doped p-wells 930 are formed on or in upper portions of the n-type silicon carbide drift region 920. Upper portions 932 of the p-wells 930 act as channel regions for the MOSFET 900. The channel regions 932 may be more lightly doped than the remainder of each p-well 930. The portions of the drift region 920 (or current spreading layer 922, if provided) that are in between the p-wells 930 are referred to as JFET regions 924. The JFET regions 924 are lightly to moderately doped n-type silicon carbide regions that are typically doped more heavily than the lower portion of the drift region 920.

Heavily-doped (n⁺) n-type silicon carbide source regions 940 are formed in upper portions of the p-wells 930. In addition, heavily-doped (p⁺) p-type silicon carbide well contact regions 934 are also formed in upper portions of the p-wells 930 and may, for example, appear as “islands” in the source regions 940, as can be seen best in FIG. 12A. As shown in FIG. 12B, a source metallization 990 is formed on the source regions 940 and the well contact regions 934.

The substrate 910, drift region 920 (including any current spreading layer 922 and the JFET regions 924), the p-wells 930 (including the channel regions 932), the well contact regions 934 and the source regions 940 comprise a semiconductor layer structure 960 of MOSFET 900. A plurality of longitudinally-extending silicon oxide gate insulating layers 970 are formed on the upper surface of the semiconductor layer structure 960. A plurality of longitudinally-extending gate electrodes 982 are formed on the respective gate insulating layers 970 opposite the semiconductor layer structure 960. A plurality of intermetal dielectric patterns 972 cover the respective gate electrodes 982 to isolate the gate electrodes 982 from the source metallization 990. Openings are provided between adjacent intermetal dielectric patterns 972 that expose the upper surface of the semiconductor layer structure 960. The source metallization 990 is formed on the intermetal dielectric patterns 972 and within these openings so as to contact the heavily-doped p-type well contact regions 934 and n-type source regions 940. A drain contact 906 is formed on the lower surface of the substrate 910.

When a voltage that exceeds a threshold voltage of MOSFET 900 is applied to the gate electrodes 982, the channel regions 932 (which are positioned directly below the gate electrodes 982 with the gate oxide layers 970 interposed therebetween) are depleted, thereby allowing current to flow from a source terminal of MOSFET 900, through the source metallization 990 and into the source regions 940, through the depleted channel regions 932 to the JFET regions 924, and then through the drift region 920 and substrate 910 to the drain contact 906. The bold arrow in FIG. 12B illustrates the current path through the left side of the “full” unit cell shown in FIG. 12B.

There typically is a trade-off in gate-controlled power semiconductor devices such as MOSFETs and IGBTs between the on-state resistance and the short circuit capabilities of the device. Low on-state resistance is desired to increase switching speed and reduce power dissipation. The on-state resistance can be reduced by, for example, increasing the conductivity of the source regions. Unfortunately, increasing the conductivity of the source regions tends to degrade the short circuit capabilities of the device.

One technique that can be used to avoid the above trade-off is to reduce the size of the unit cells, thereby increasing the number of unit cells per unit area. This decreases the on-state current density within each unit cell, which effectively lowers the on-state resistance of the device. This techniques is used in the above-described embodiments of the present invention to provide enhanced performance. In particular, when the size of each unit cell is reduced and the current rating of the device is held constant, each unit cell carries smaller on-state current levels when operating at the maximum current rating (since there are more unit cells). As such, the sizes of the JFET gaps and the ohmic contact area can be reduced without increasing the on-state resistance. In other words, the short circuit capabilities of the device may be improved without increasing the on-state resistance thereof. This technique may work well in gate trench devices, but there are limitations in planar gate (i.e., non-trench) devices as to how much this technique can improve performance, because shrinking the size of the JFET gaps results in an exponential increase in the on-state resistance in the JFET regions, and because the smaller size of the source regions results in an exponential increase in the conductivity thereof.

As shown in FIGS. 11A-11C, pursuant to the techniques according to embodiments of the present invention, it is also possible to improve both the on-state resistance performance and short circuit capabilities of a planar gate-controlled power semiconductor device through efficient reduction in the sizes of the unit cells thereof by changing the location of the well contact regions 134. As shown above with reference to FIGS. 12A-12B, in a conventional planar gate vertical power MOSFET having a “stripe” gate electrode configuration, the gate electrodes 982 extend in parallel to each other with the opposed sides of each gate electrode 982 extending over the outer edges of respective source regions 940. The well contact regions 934 are positioned in between each pair of source regions 940 and the source metallization 990 directly contacts the source regions 940 and the well contact regions 934 in the gaps between adjacent gate electrodes 982. Thus, in power MOSFET 900, the longitudinal axes of the ohmic lines 992 extend in parallel to the longitudinal axes of the gate electrodes 982. In contrast, as shown in FIGS. 11A-11C, by having the well contact regions 134 extend perpendicular to the source regions 140A and the gate electrodes 882 (i.e., longitudinal axes of the well contact regions 134 extend perpendicular to the longitudinal axes of the source regions 140A and to the longitudinal axes of the gate electrodes 882), the locations where the source metallization 190 contacts the semiconductor layer structure 860 (i.e., the ohmic lines 192) also extend perpendicular to the source regions 140A and to the gate electrodes 882. As a result, the source metallization 190 need not contact the semiconductor layer structure 860 in long stripes between adjacent gate electrodes 882, and hence it is not necessary to form dielectric spacers on the semiconductor layer structure 860 in between adjacent gate electrodes 882 in order to isolate the gate electrodes 882 from the source metallization 190. As such, the spacing between adjacent gate electrodes 882 may be reduced, which reduces the size of the unit cells. In other words, since the ohmic lines 192 extend perpendicular to the source regions 140A and the gate electrodes 882, the distance between adjacent gate electrodes 882 may be reduced since there is no need for the space between adjacent gate electrodes 882 to be wide enough to allow for both insulating layers that isolate the source metallization 190 from the gate electrodes 882 while leaving gaps between the adjacent gate electrodes 882 that can be filled with the source metallization 190 with good gap fill properties. Instead, except for at the positions of the ohmic lines 192, an insulating layer 172 covers the upper surface of the source regions 140A and the source metallization 190 is formed on top of this insulating layer 172. Since there is no well contact region 134 provided between adjacent source regions 140A and no source metallization 190 filling the gap, the distance between adjacent gate electrodes 882 can be reduced, for example, by about the width of the well contact regions 934 provided in the conventional planar gate MOSFET 900 of FIGS. 12A-12B, while keeping the widths of each source region 140A the same. In other words, the size of each unit cell may be reduced significantly without changing the widths of the source regions 140A or the conductivity (i.e., doping concentration) thereof. The number of unit cells per unit area thus increases, which means that for a given device on-state current rating, the amount of current carried by each unit cell is reduced, thereby effectively decreasing the JFET resistance (since the JFET regions can have the same size yet carry smaller amounts of current). Thus, as the above explanation makes clear, power MOSFET 800 of FIGS. 11A-11C may provide an improved trade-off between on-state resistance and short circuit capabilities (i.e., it allows the performance of one or both parameters to be improved while at least maintaining the performance of the other parameter).

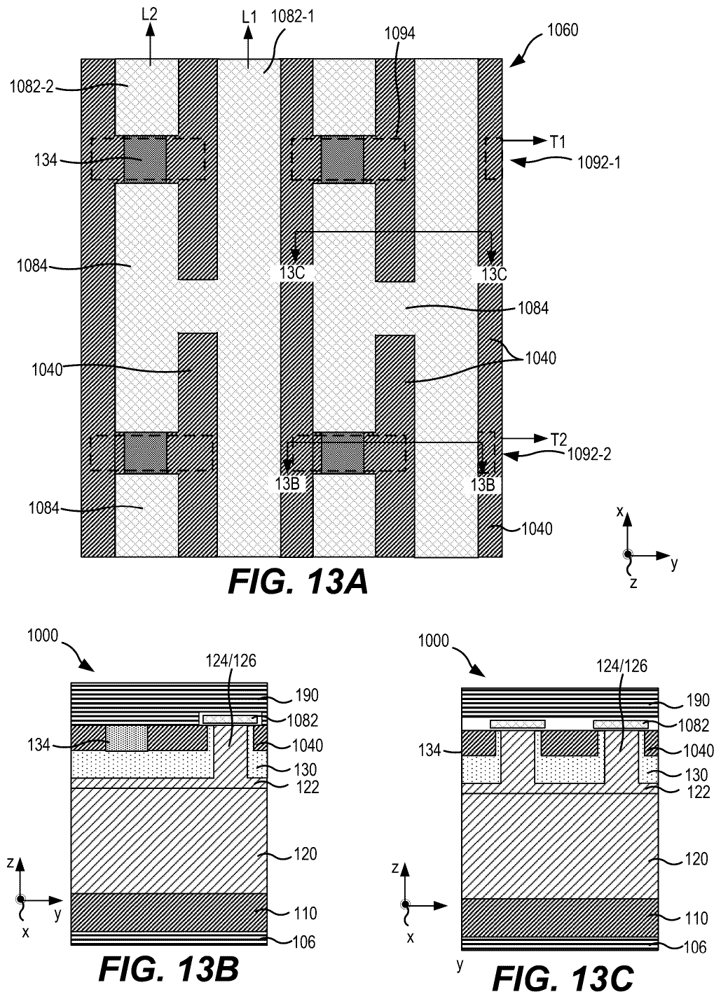

While FIGS. 11A-11C illustrate one design for a planar gate power MOSFET that exhibits this improved tradeoff, embodiments of the present invention are not limited thereto. FIGS. 13A-17B and 19A-20 illustrate a variety of additional example planar gate power MOSFETs that may exhibit improved performance using the techniques according to embodiments of the present invention.

FIGS. 13A-13C illustrate a planar gate power MOSFET 1000 according to further embodiments of the present invention. In particular, FIG. 13A is a schematic plan view of a power MOSFET 1000 with the source metallization and upper dielectric layers omitted, while FIGS. 13B and 13C are schematic cross-sectional views taken along lines 13B-13B, 13C-13C, respectively, of FIG. 13A. In FIG. 13B, the source metallization and upper dielectric layers that are omitted in FIG. 13A are illustrated to provide context.

As can be seen by comparing FIGS. 11A-11C to FIGS. 13A-13C, power MOSFET 1000 is similar to power MOSFET 800, with the primary difference between the two devices being that MOSFET 800 has continuous ohmic lines 192-1, 192-2, while power MOSFET 1000 has discontinuous ohmic lines 1092-1, 1092-2. Since the ohmic lines 1092 are discontinuous in power MOSFET 1000, some of the gate electrodes 1082 may extend continuously in the x-direction, as shown in FIG. 13A. In the depicted embodiment, every other gate electrode 1082 is a continuous gate electrode that extends through gaps in the discontinuous ohmic lines 1092, but embodiments of the present invention are not limited thereto. Using discontinuous ohmic lines 1092-1, 1092-2 may reduce the amount of contact area between the source metallization 190 and the semiconductor layer structure 1060 as compared to power MOSFET 800, which may increase the on-state resistance to a degree. However, the amount of channel area in power MOSFET 1000 is increased as compared to power MOSFET 800 since the continuous gate electrodes 1082 have increased channel area as compared to the discontinuous gate electrodes 882 in power MOSFET 800. The additional channel area reduces the on-state resistance. Thus, the on-state resistance performance may be improved by selecting the degree to which the source metallization 190 contacts the semiconductor layer structure 1060.

Gate electrode extensions 1084 are provided in power MOSFET 1000 that connect each discontinuous gate electrode 1082 to one of the continuous gate electrodes 1082. The gate extensions 1084 provide a convenient way of delivering the gate signal to the discontinuous gate electrodes 1082.

During on-state operation, the on-state current flows through the source metallization 190 and into the semiconductor layer structure 1060 at the locations where the source metallization 190 physically contacts the semiconductor layer structure 1060 (i.e., along the discontinuous ohmic lines 1092). Once the on-state current enters the semiconductor layer structure 1060, the current primarily flows in the x-direction through the source regions 1040 to spread throughout each unit cell, and also flows in the y-direction through the channel regions 1232 in the p-wells 130 into the JFET regions 124. The current then flows vertically (i.e., in the z-direction) through the JFET regions 124, the drift region 120 and the semiconductor substrate 110 to the drain electrode 106. As discussed above with respect to power MOSFET 100, this means that the on-state current must flow laterally through the source regions 1040 to spread throughout the unit cell transistors of power MOSFET 1000. Since even highly-doped n-type silicon carbide that forms the source regions 1040 has a much higher specific resistance than the metals that comprise the source metallization 190, this lateral current flow increases the on-state resistance of power MOSFET 1000 as compared to the conventional power MOSFET 900 of FIGS. 12A-12B. However, the resistance of the source regions 1040 may be much lower than, for example, the resistance of the JFET regions 124, and hence may only have a small contribution to the overall on-state resistance of power MOSFET 1000. As such, decreases in the on-state resistance that are obtained by reducing the size of each unit cell (and hence the amount of current flow through each unit cell) may more than offset the slight increase in the on-state resistance caused by the lateral current flow through the source regions 1040. Moreover, while not shown in FIGS. 13A-13C, in some embodiments, the upper surfaces of the source regions 1040 may be converted into a silicide layer via a silicidation process. Silicides have much lower resistances as compared to highly-doped n-type silicon carbide, and hence the inclusion of such a silicide layer on the upper portion of each source region 1040 may provide a low resistance path for the lateral on-state current through the source regions 1040 as the current flowing from the source metallization 190 will almost all flow into the silicided region to spread laterally throughout the device. The silicide layer may be formed, for example, during a silicidation step that is used to form an ohmic contact silicide layer of the source metallization 190 (if provided), but the silicide layer that is formed on each source region 1040 to allow lateral current spread is not considered to be part of the source metallization 190

Referring to FIGS. 13A-13C, it can be seen that a semiconductor device is provided in the form of power MOSFET 1000 that comprises a semiconductor layer structure 1060 comprising a drift region 120 having a first conductivity type (here, n-type). The semiconductor devices 1000 further comprise a first gate electrode 1082-1 on the semiconductor layer structure 1060 that extends along a first longitudinal axis L1 above the drift region 124, and a second gate electrode 1082-2 on the semiconductor layer structure 1060, where the second gate electrode 1082-2 comprises a plurality of second gate electrode segments 1084 that are spaced-apart from each other along a second longitudinal axis L2 above the drift region 124. The semiconductor device 1000 further comprises a first ohmic line 1092-1 that extends in the semiconductor layer structure 1060 along a first transverse axis T1. The first and second longitudinal axes L1, L2 cross the first transverse axis T1 when the semiconductor device 1000 is viewed from above.

The first longitudinal axis L1 may be parallel to the second longitudinal axis L2. The first transverse axis T1 may be perpendicular to the first and second longitudinal axes L1, L2. In some embodiments, the first ohmic line 1092-1 comprises a plurality of first ohmic line segments 1094 that are spaced-apart from each other along the first transverse axis T1, and the first gate electrode 1082-1 extends continuously in the semiconductor layer structure 1060 between a first of the plurality of first ohmic line segments 1094 and a second of the plurality of first ohmic line segments 1094.

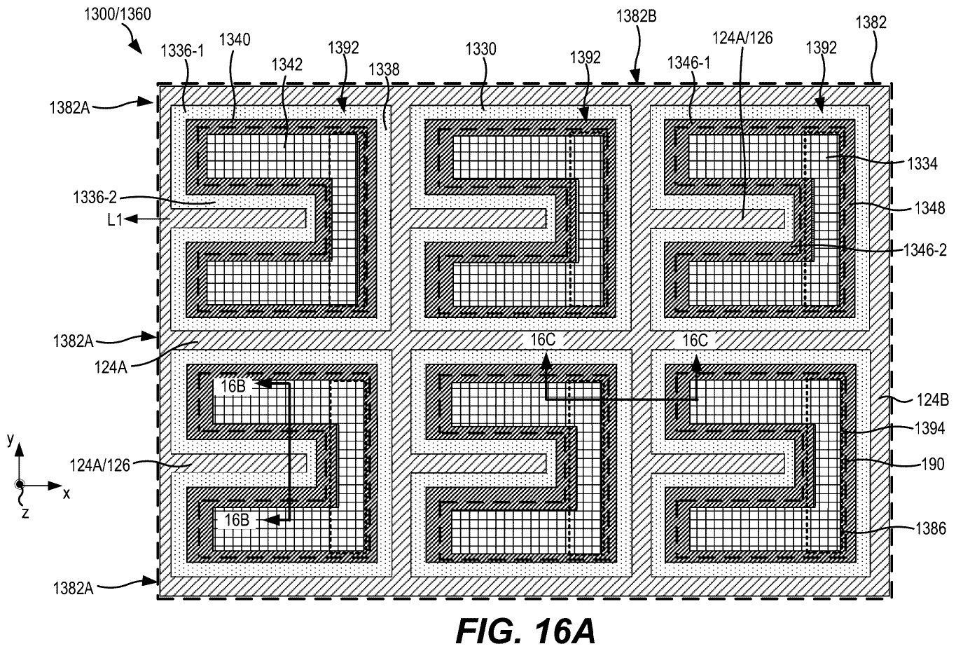

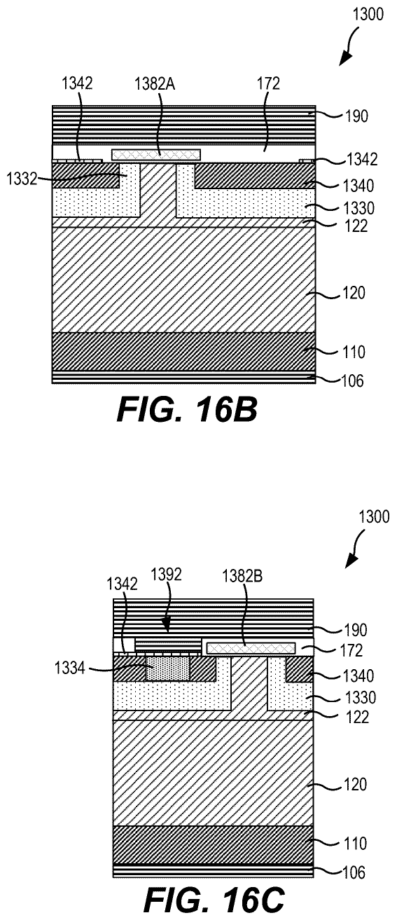

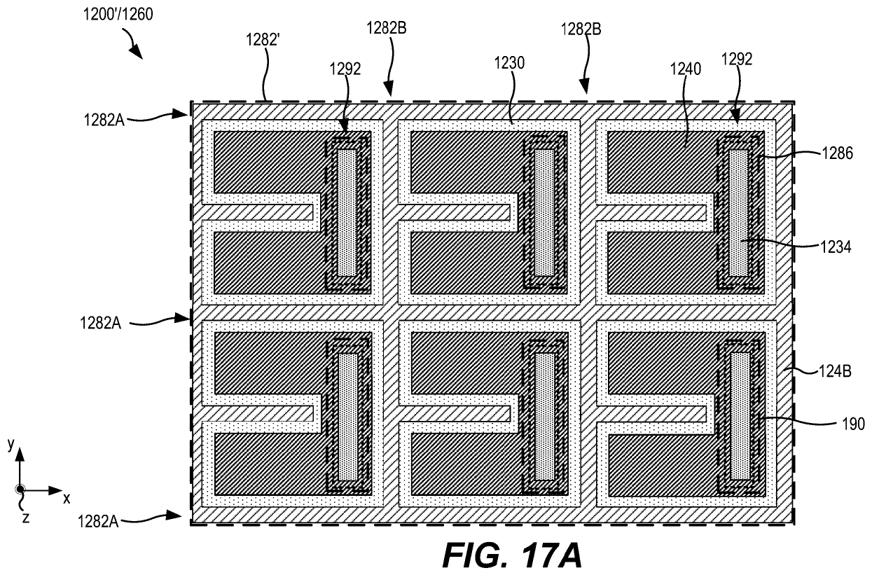

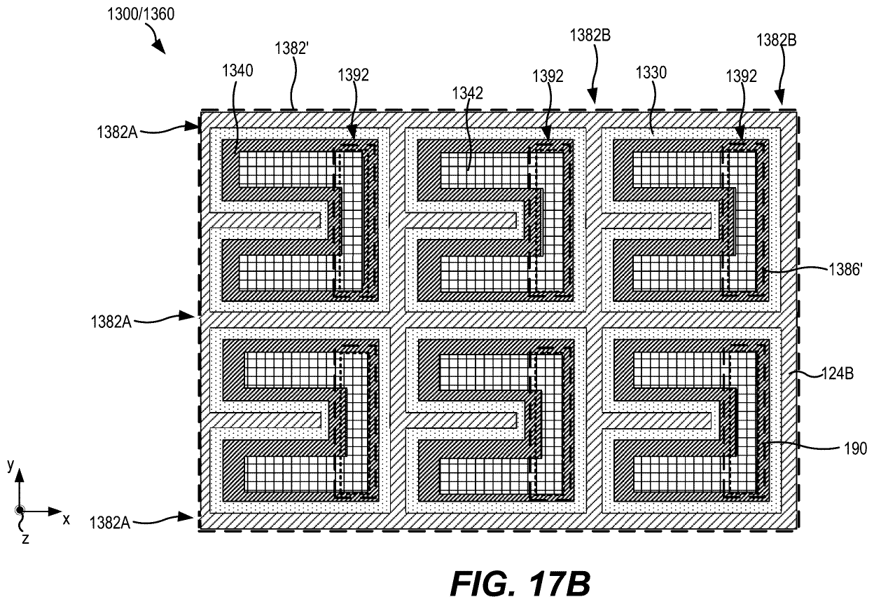

The semiconductor device 1000 may further comprise a second ohmic line 1092-2 that extends in the semiconductor layer structure 1060 along a second transverse axis T2 that is parallel to the first transverse axis T1. The semiconductor layer structure 1060 also includes a first source region 1040 that has the first conductivity type. The first source region 1040 extends along a third longitudinal axis L3 that is parallel to and in between the first and second longitudinal axes L1, L2 when the semiconductor device 1000 is viewed from above. Each of the first through third longitudinal axes L1, L2, L3 may extend in a first direction (here the x-direction). The semiconductor device 1000 may further comprise a dielectric layer 172. In some embodiments, the dielectric layer 172 may directly contact and cover a portion of the first source region 1040 that is in between the first transverse axis T1 and the second transverse axis T2. While not shown in FIGS. 13A-13C, in other embodiments a silicide layer that is part of the source metallization 190 may be formed on an upper surface of the portion of the first source region 1040 that is in between the first transverse axis T1 and the second transverse axis T2 so that the silicide layer is in between the source region 1040 and the dielectric layer 172. The power semiconductor devices discussed below with reference to FIGS. 16A-16C and 17B include such silicide layers, which can provide a low resistance path for carrying the on-state current from the source metallization 190 to the channel regions. The dielectric layer 172 may directly contact and cover a portion of the silicide layer that is in between the first transverse axis T1 and the second transverse axis T2.

The semiconductor layer structure 1060 may further comprise a well region 130 having a second conductivity type (here, p-type) that is in between the drift region 120 and the first source region 1040. The semiconductor device 1000 is configured so that during on-state operation a source-drain current flows in the first direction through the first source region 1040 or, if provided, through the above-discussed silicide layer.

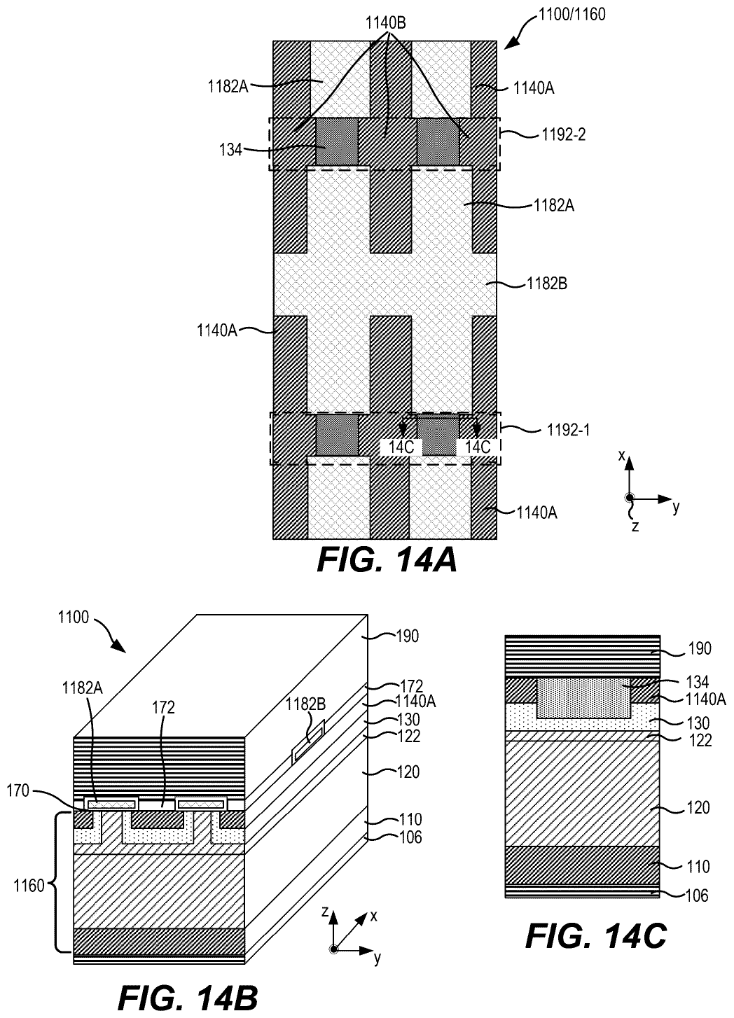

FIGS. 14A-14C illustrate a planar gate power MOSFET 1100 according to further embodiments of the present invention. In particular, FIG. 14A is a schematic plan view of power MOSFET 1100 with the source metallization and upper dielectric layers omitted. FIG. 14B is a schematic perspective view of power MOSFET 1100 and FIG. 14C is a schematic cross-sectional view taken along lines 14C-14C of FIG. 14A. In FIGS. 14B and 14C, the source metallization and dielectric layers that are omitted in FIG. 14A are illustrated to provide context.

Power MOSFET 1100 is similar to power MOSFET 800 of FIGS. 11A-11C, with the primary difference between that power MOSFET 800 has a so-called “stripe” gate electrode design where all of the gate electrodes 882 extend in the same direction (the x-direction FIGS. 11A-11C), while power MOSFET 1100 has a “mesh” design where a first set of gate electrodes 1182A extend in a first direction (the x-direction FIGS. 14A-14C) and a second set of gate electrodes 1182B extend in a second direction (the y-direction FIGS. 14A-14C). The first and second directions are typically perpendicular to each other and parallel to the primary surfaces of the semiconductor layer structure 1160 of power MOSFET 1100.

Power MOSFET 1100 is shown as having continuous ohmic lines 1192, continuous second gate electrodes 1182B, and discontinuous first gate electrodes 1182A. It will be appreciated that in other embodiments power MOSFET 1100 may be modified to have discontinuous ohmic lines 1192 and both continuous and discontinuous first gate electrodes 1182A. Such an embodiment is effectively a mesh gate variation of power MOSFET 1000 of FIGS. 13A-13C.

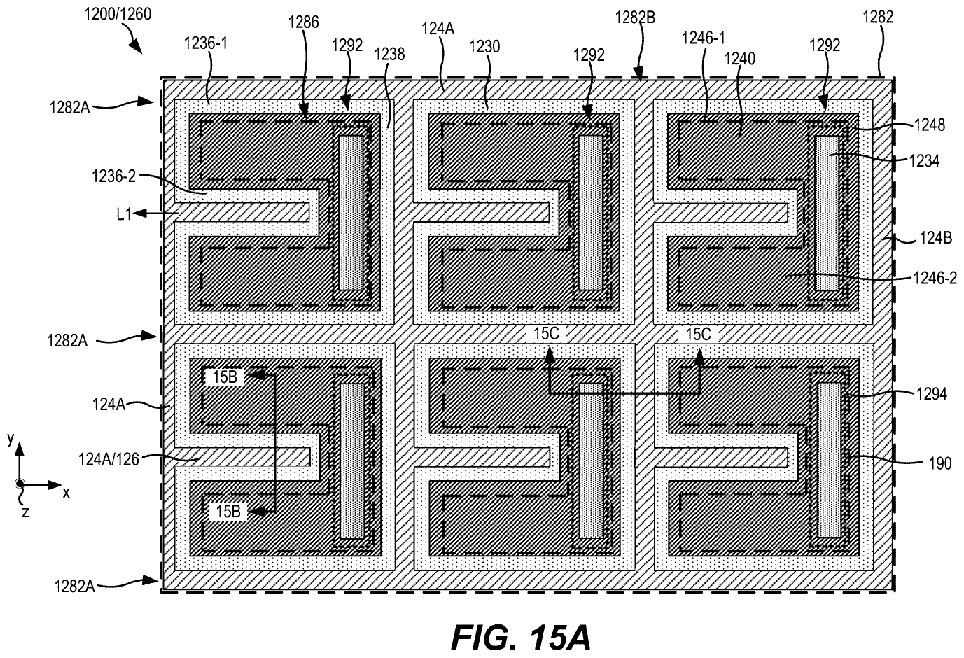

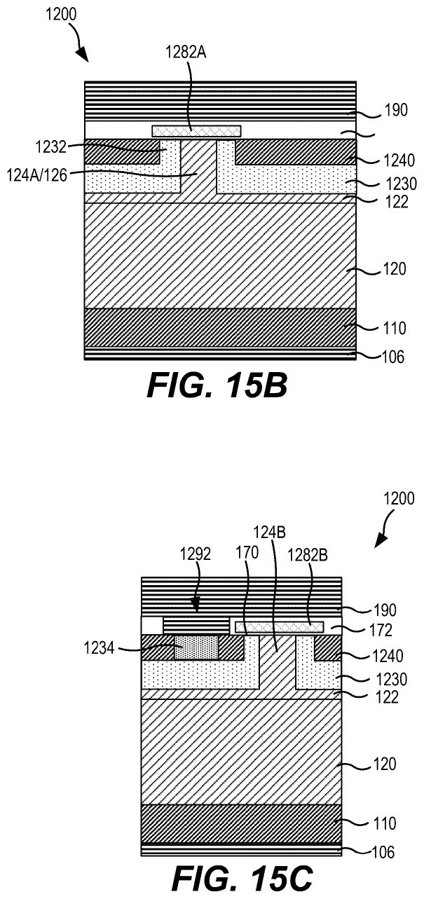

FIGS. 15A-15C illustrate a planar gate vertical power MOSFET 1200 according to further embodiments of the present invention. In particular, FIG. 15A is a schematic plan view of an upper surface of a semiconductor layer structure 1260 of power MOSFET 1200, while FIGS. 15B and 15C are schematic cross-sectional views of power MOSFET 1200 taken along line 15B-15B and 15C-15C, respectively, of FIG. 15A. In FIGS. 15B and 15C, the first and second gate electrodes 1282A, 1282B, the source metallization 190 and the upper dielectric layers 170, 172 that are omitted in FIG. 15A are illustrated to provide context. Power MOSFET 1200 has a mesh gate design and discontinuous ohmic lines. As such, power MOSFET 1200 can be viewed as a combination of power MOSFET 1000 of FIGS. 13A-13C (a “stripe” power MOSFET with discontinuous ohmic lines) and power MOSFET 1100 of FIGS. 14A-14C (a “mesh” power MOSFET with continuous ohmic lines). While the first and second gate electrodes 1282A, 1282B and the source metallization 190 are not shown in FIG. 15A, the locations where the first and second gate electrodes 1282A, 1282B are formed on the upper surface of the semiconductor layer structure 1260 are indicated in FIG. 15A using dashed lines, and the locations where the source metallization 190 directly contacts the semiconductor layer structure 1260 (i.e., the ohmic lines) are indicated in FIG. 15A using dotted lines.

As shown in FIG. 15A, power MOSFET 1200 has a mesh gate electrode design with a first set of gate electrodes 1282A and a second set of gate electrodes 1282B. Each first gate electrode 1282A extends in a first direction (the x-direction) and each second gate electrode 1282B extends in a second direction (the y-direction) that is perpendicular to the first direction. The first and second gate electrodes 1282A, 1282B merge into each other to form a monolithic gate electrode structure 1282. The second gate electrodes 1282B are all continuous gate electrodes, while half (specifically, every other) of the first gate electrodes 1282A are continuous gate electrodes while the other half of the first gate electrodes 1282A are discontinuous gate electrodes.

Referring to FIGS. 15B and 15C, the semiconductor layer structure 1260 comprises a heavily-doped n-type semiconductor substrate 110, an n-type drift region 120 that is formed on the upper surface of the substrate 110, a plurality of p-wells 130 that are formed on the drift region 120, heavily-doped n-type source regions 1240 and heavily-doped p-type well contact regions 134 that are formed in the respective well regions 1230, and n-type first and second JFET regions 124A, 124B that are formed in between adjacent p-wells 1230 and within gaps in the p-wells 1230. The first JFET regions 124A have respective longitudinal axes that extend in the x-direction and include a plurality of continuous first JFET regions 124A and a plurality of discontinuous first JFET regions 124A that each comprise a plurality of JFET region segments 126 that extend along respective longitudinal axes in the x-direction. The second JFET regions 124B are continuous JFET regions and have respective longitudinal axes that extend in the y-direction. The first JFET regions 124A extend underneath the respective first gate electrodes 1282A, with the continuous first JFET regions 124A extending underneath the continuous first gate electrodes 1282A, and the discontinuous first JFET regions 124A extending underneath respective ones of the discontinuous first gate electrodes 1282A. The continuous second JFET regions 124B extend underneath the respective continuous second gate electrodes 1282B.

Referring again to FIG. 15A, each p-well 1230 has a U-shape when power MOSFET 1200 is viewed from above. Each source region 1240 is within an upper portion of a respective one of the p-wells 1230, and each source region 1240 also has a U-shape when power MOSFET 1200 is viewed from above. Each U-shaped p-well 1230 has first and second well leg segments 1236-1, 1236-2 and a base well segment 1238 that connects first ends of the first and second well leg segments 1236-1, 1236-2. Similarly, each U-shaped source region 1240 has first and second source leg segments 1246-1, 1246-2 and a base source segment 1248 that connects first ends of the first and second source leg segments 1246-1, 1246-2. The well contact regions 1234 extend through the base source segments 1248 of the respective source regions 1240. Each JFET region segment 126 of the discontinuous first JFET regions 124A extends in between the first and second well leg segments 1236-1, 1236-2 of a respective one of the p-wells 1230. As a result, each p-well 1230 directly contacts three of the fours sides of a respective one of the JFET region segments 126.

As can also be seen in FIG. 15A, power MOSFET 1200 has a plurality of discontinuous ohmic lines 1292. The ohmic lines 1292 extend in the y-direction. As discussed above, the ohmic lines 1292 refer to longitudinally-extending combinations of the source region(s) 1240 and the well contact region(s) 1234 that are directly contacted by the source metallization 190. Each discontinuous ohmic line 1292 comprises a plurality of ohmic line segments 1294. The continuous first gate electrodes 1282A extend in the gaps between adjacent ohmic line segments 1294. The portions of p-wells 1230 that are visible in FIG. 15A will act as channel regions (i.e., the on-state current will flow from the source regions 1240 through the portions of the p-wells 130 that are visible in FIG. 15A.

As discussed above, power MOSFET 1200 includes a plurality of continuous first gate electrodes 1282A that extend in the x-direction, a plurality of discontinuous first gate electrodes 1282A that extend in the x-direction, and a plurality of continuous second gate electrodes 1282B that extend in the y-direction. The first and second gate electrodes 1282A, 1282B intersect each other to form a monolithic gate electrode 1282. As shown in FIGS. 15B-15C, a gate oxide layer 170 is provided between each first gate electrode 1282A and the semiconductor layer structure 1260 and between each second gate electrode 1282B and the semiconductor layer structure 1260. As shown in FIG. 15A, the monolithic gate electrode 1282 may comprise a continuous sheet of metal that has a plurality of U-shaped openings formed therein when power MOSFET 1200 is viewed from above. The source metallization 190 extends into a selected region of each U-shaped opening, and a dielectric material (not shown) may fill the remainder of each U-shaped opening in the gate electrode 1282.

FIGS. 16A-16C illustrate a planar gate power MOSFET 1300 according to further embodiments of the present invention. In particular, FIG. 16A is a schematic plan view of an upper surface of a semiconductor layer structure 1360 of power MOSFET 1300, while FIGS. 16B and 16C are schematic cross-sectional views of power MOSFET 1300 taken along lines 16B-16B and 16C-16C, respectively, of FIG. 16A. In FIGS. 16B and 16C, the gate electrodes 1382A, 1382B, the source metallization 190 and the upper dielectric layers that are omitted in FIG. 16A are illustrated to provide context. While the gate electrodes 1382A, 1382B and the source metallization 190 are not shown in FIG. 16A, the locations where the first and second gate electrodes 1382A, 1382B are formed on the upper surface of the semiconductor layer structure 1360 are indicated in FIG. 16A using dashed lines, and the locations where the source metallization 190 directly contacts the semiconductor layer structure 1360 are indicated in FIG. 16A using dotted lines.

As can be seen by comparing FIGS. 16A-16C to FIGS. 15A-15C, power MOSFET 1300 is almost identical to power MOSFET 1200, with the one difference being that in power MOSFET 1300 silicide layers 1342 are formed on the upper surfaces of the source regions 1340. The silicide layers 1342 provide low-resistance paths for the lateral on-state current so that the current can spread throughout the silicide layers 1342 before entering the source regions 1340. As shown in FIGS. 16A and 16C, the silicide layer 1342 may also be formed on the well contact regions 1334. As power MOSFET 1300 is otherwise identical to power MOSFET 1200, further description thereof will be omitted here.

In the embodiments of FIGS. 15A-15C and 16A-16C, the first and second gate electrodes provided in each power MOSFET merge together to form monolithic gate electrodes 1282, 1382. Each monolithic gate electrode 1282, 1382 includes a plurality of U-shaped openings 1286, 1386 when the MOSFETS 1200, 1300 are viewed from above. As discussed above, power MOSFETS 1200, 1300 each have U-shaped source regions 1240, 1340 when viewed from above, with a well contact region 1234, 1334 provided within the base of the respective U-shaped source regions 1240, 1340. The U-shaped openings in the monolithic gate electrodes 1282, 1382 are positioned above the respective U-shaped source regions 1240, 1340, with each U-shaped opening being slightly smaller than the U-shaped source regions 1240, 1340. The monolithic gate electrodes 1282, 1382 of MOSFETS 1200, 1300 need not extend completely over the legs of the U-shaped source regions 1240, 1340 because the monolithic gate electrodes 1282, 1382 need only overlie the channel regions 1232, 1332, which are formed in the upper portions of the p-wells 130 (i.e., in the portions of the p-wells 1230, 1330 that are visible in FIGS. 15A and 16A), and edges of the source regions 1240, 1340 for proper operation of the MOSFETS 1200, 1300.

Referring to FIGS. 15A-15C and 16A-16C, it can be seen that semiconductor devices 1200, 1300 are provided in the form of power MOSFETS 1200, 1300 that each comprise a semiconductor layer structure 1260, 1360 comprising a drift region 120 having a first conductivity type (here, n-type), a source region 1240, 1340 having the first conductivity type (here n-type) and a well region 1230, 1330 having a second conductivity type (here p-type) that is between the drift region 120 and the source region 1240, 1340. The source region 1240, 1340 has a U-shape when the semiconductor device 1200, 1300 is viewed from above.

The semiconductor layer structure 1260, 1360 may further comprise a well contact region 1234, 1334 having the second conductivity type within the U-shaped source region 1240, 1340. The well region 1230, 1330 may also have a U-shape when the device is viewed from above, and the source region 1240, 1340 may be formed within an upper portion of the well region 1230, 1330. The semiconductor layer structure 1260, 1360 may further comprise a JFET region segment 126 of a first JFET region 124A that is positioned in between first and second legs of the U-shaped source region 1240, 1340 when the semiconductor device 1200, 1300 is viewed from above. The JFET region segment 126 may have the first conductivity type. The semiconductor device may also comprise a monolithic gate electrode 1282, 1382 on an upper surface of the semiconductor layer structure 1260, 1360, the monolithic gate electrode 1282, 1382 comprising a plurality of U-shaped openings 1286, 1386 (see U-shaped regions formed by dashed lines in FIGS. 15A and 16A) when the semiconductor device is viewed from above 1200, 1300.

The source region 1240, 1340 may be one of a plurality of source regions 1240, 1340 and the well region 1230, 1330 may be one of a plurality of well regions 1230, 1330. Each of the plurality of source regions 1240, 1340 may have a U-shape when the semiconductor device 1200, 1300 is viewed from above, and each of the plurality of well regions 1230, 1330 may similarly have a U-shape when the semiconductor device 1200, 1300 is viewed from above. The source regions 1240, 1340 are within upper portions of the respective well regions 1230, 1330. Moreover, the source regions 1240, 1340 may be arranged in rows and columns when the semiconductor device 1200, 1300 is viewed from above. Additionally, the semiconductor layer structure 1260, 1360 may further comprise a plurality of well contact regions 1234, 1334 having the second conductivity type, where each well contact region 1234, 1334 is within a respective one of the U-shaped source regions 1240, 1340. The well contact regions 1234, 1334 in a first of the columns of source regions 1240, 1340 have longitudinal axes that extend along a first axis. The well contact regions 1234, 1334 and portions of the source regions 1240, 1340 in which the well contact regions 1234, 1334 are positioned form a first ohmic line 1292-1, 1392-1 that comprises a plurality of spaced-apart ohmic line segments 1294, 1394. The semiconductor device further comprises a source metallization 190 on an upper surface of the semiconductor layer structure 1260, 1360, and the source metallization 190 directly contacts the semiconductor layer structure 1260, 1360 along the first ohmic line 1292-1, 1392-1.

The semiconductor layer structure 1260, 1360 may further comprise a plurality of first JFET regions 124A having the first conductivity type. The first JFET regions 124A extend in a first direction in the semiconductor layer structure 1260, 1360 when the semiconductor device 1200, 1300 is viewed from above. The semiconductor layer structure 1260, 1360 may further comprise a plurality of second JFET regions 124B having the first conductivity type that extend in a second direction in the semiconductor layer structure 1260, 1360 when the semiconductor device 1200, 1300 is viewed from above. The first direction crosses the second direction and is perpendicular to the second direction in the depicted embodiments. A first subset of the first JFET regions 124A may extend continuously in between respective pairs of adjacent spaced-apart ohmic line segments 1294, 1394, while a second subset of first JFET regions 124A may each comprise a plurality of spaced-apart JFET region segments 126 that extend in the first direction. Each of the second JFET regions 124B may extend continuously in parallel to the first ohmic line 1292-1, 1392-1.

Still referring to FIGS. 15A-15C and 16A-16C, it can be seen that semiconductor devices 1200, 1300 are provided in the form of power MOSFETS 1200, 1300 that each comprise a semiconductor layer structure 1260, 1360 comprising a drift region 120 having a first conductivity type (here, n-type), a source region 1240, 1340 having the first conductivity type (here n-type) and a well region 1230, 1330 having a second conductivity type (here p-type) that is between the drift region 120 and the source region 1240, 1340. The drift region 120 comprises a JFET region segment 126 that extends along a first longitudinal axis L1, and the well region 1230, 1330 directly contacts at least three, but less than all, of a plurality of sidewalls of the JFET region segment 126.

A channel region 1232, 1332 that is configured to be inverted during on-state operation of the semiconductor device 1200, 1300 is defined in the well region 1230, 1330 so that the channel region 1232, 1332 extends adjacent all of the at least three of the plurality of sidewalls of the JFET region segment 126. The JFET region segment 126 may have a total of four sidewalls in some embodiments, as shown. The JFET region segment 126 may be part of a first JFET region 124A that extends along the first longitudinal axis L1, the first JFET region 124A comprising a plurality of spaced-apart JFET region segments 126. The well region 1230, 1330 may be one of a plurality of well regions 1230, 1330, and each of the well regions 1230, 1330 may directly contact at least three, but less than all, of the sidewalls of a respective one of the JFET region segments 126 in the first JFET region 124A.

As best seen in FIGS. 15A and 16A, an upper portion of the well region 1230, 1330 has first and second well leg segments 1236-1, 1236-2; 1336-1, 1336-2 that extend in parallel to the first longitudinal axis L1 and a well base segment 1238, 1338 that extends between and connects to first ends of the first and second well leg segments 1236-1, 1236-2; 1336-1, 1336-2 when the semiconductor device 1200, 1300 is viewed from above. The JFET region segment 126 is positioned in between the first and second legs 1236-1, 1236-2; 1336-1, 1336-2 when the semiconductor device 1200, 1300 is viewed from above.

The source region 1240, 1340 similarly has first and second source leg segments 1246-1, 1246-2; 1346-1, 1346-2 that extend in parallel to the first longitudinal axis L1 and a source base segment 1248, 1348 that extends between and connects to first ends of the first and second source leg segments 1246-1, 1246-2; 1346-1, 1346-2 when the semiconductor device 1200, 1300 is viewed from above. The source region 1240, 1340 is within an upper portion of the well region 1230, 1330. The semiconductor layer structure 1260, 1360 further comprises a well contact region 1234, 1334 having the second conductivity type that extends through the source base segment 1248, 1348 to connect to the well region 1230, 1330. The semiconductor device further comprises a source metallization 190 that directly contacts the well contact region 1234, 1334. The source metallization 190 is typically a multilayer structure that may include, for example, a bulk metallization layer, and one or more of adhesion layers, barrier layers, ohmic contact layers (e.g. a silicide layer). Moreover, power MOSFET 1300 further includes a silicide layer 1342 that is separate from the source metallization 190. The silicide layer 1342 may be formed directly on the semiconductor layer structure 1360 in regions where the source metallization 190 does not contact the semiconductor layer structure 1360. As shown in FIG. 16A, the silicide layer 1342 may be formed on and directly contact the first and second source leg segments 1346-1, 1346-2. A dielectric layer 172 may cover the silicide layer 1342.

The semiconductor device 1200, 1300 may further comprise a monolithic gate electrode 1282, 1382 on an upper surface of the semiconductor layer structure 1260, 1360. The monolithic gate electrode 1282, 1382 may include a plurality of U-shaped openings when the semiconductor device 1200, 1300 is viewed from above. Alternatively, as shown in FIGS. 17A and 17B (discussed below), the semiconductor device may instead include a monolithic gate electrode 1282′, 1382′ on an upper surface of the semiconductor layer structure 1260, 1360 that includes a plurality of rectangular openings that are arranged in rows and columns when the semiconductor device 1200′, 1300′ is viewed from above.

Still referring to FIGS. 15A-15C and 16A-16C, it can be seen that semiconductor devices are provided in the form of power MOSFETS 1200, 1300 that each comprise a semiconductor layer structure 1260, 1360, a gate electrode 1282, 1382 on the semiconductor layer structure 1260, 1360, and a gate oxide layer 170 interposed in between the gate electrode 1282, 1382 and the semiconductor layer structure 1260, 1360. The gate electrode 1282, 1382 includes a plurality of U-shaped openings 1286, 1386. The plurality of U-shaped openings may be arranged in rows and columns when the semiconductor device 1200, 1300 is viewed from above, as shown in FIGS. 15A and 16A.

Referring to FIGS. 16A-16C, a semiconductor device 1300 is provided that comprises a semiconductor layer structure 1360 that includes a source region 1340 having the first conductivity type, a silicide layer 196 on the source region 1340, and a dielectric layer 172 on the silicide layer 196 so that the silicide layer 196 is in between and directly contacts both the source region 1340 and the dielectric layer 172. The U-shaped openings 1286, 1386 may be filled with a dielectric layer and the source metallization 190.

FIGS. 17A and 17B are plan views of MOSFETS 1200′ and 1300′ that are modified versions of MOSFETS 1200 and 1300, respectively. MOSFETS 1200′ and 1300′ may be identical to MOSFETS 1200 and 1300, respectively, except that the monolithic gate electrodes 1282′, 1382′ in MOSFETS 1200′, 1300′ have rectangular openings 1286′, 1386′ instead of U-shaped openings 1286, 1386. Consequently, in MOSFETS 1200′, 1300′ the monolithic gate electrodes 1282′, 1382′ cover the legs of the U-shaped source regions 1240, 1340. Operation of MOSFETS 1200′, 1300′ may be identical to the operation of MOSFETs 1200, 1300, respectively, since extending the monolithic gate electrodes to cover the legs of the U-shaped source regions 1240, 1340 does not change how the devices operate.

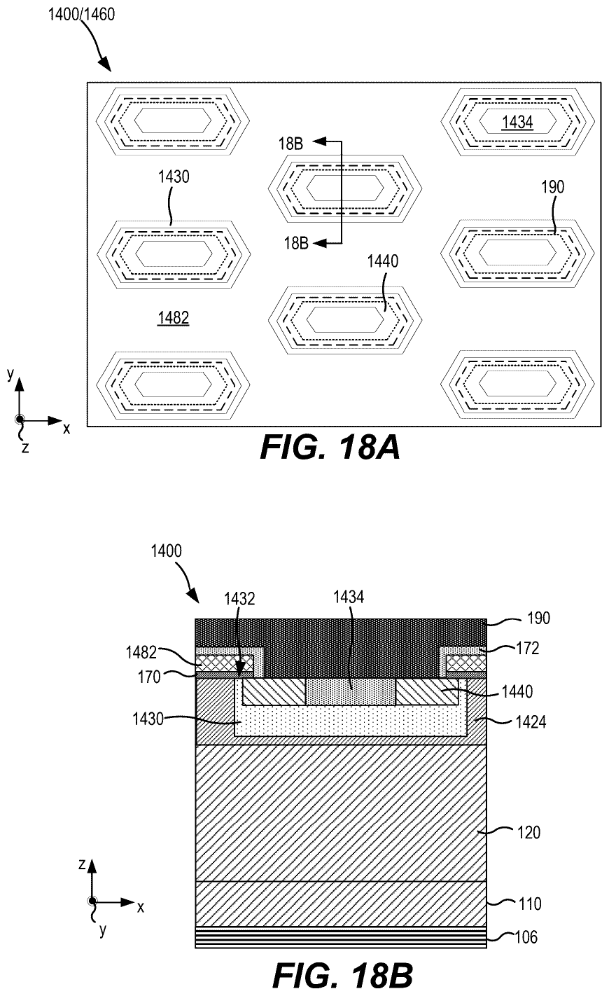

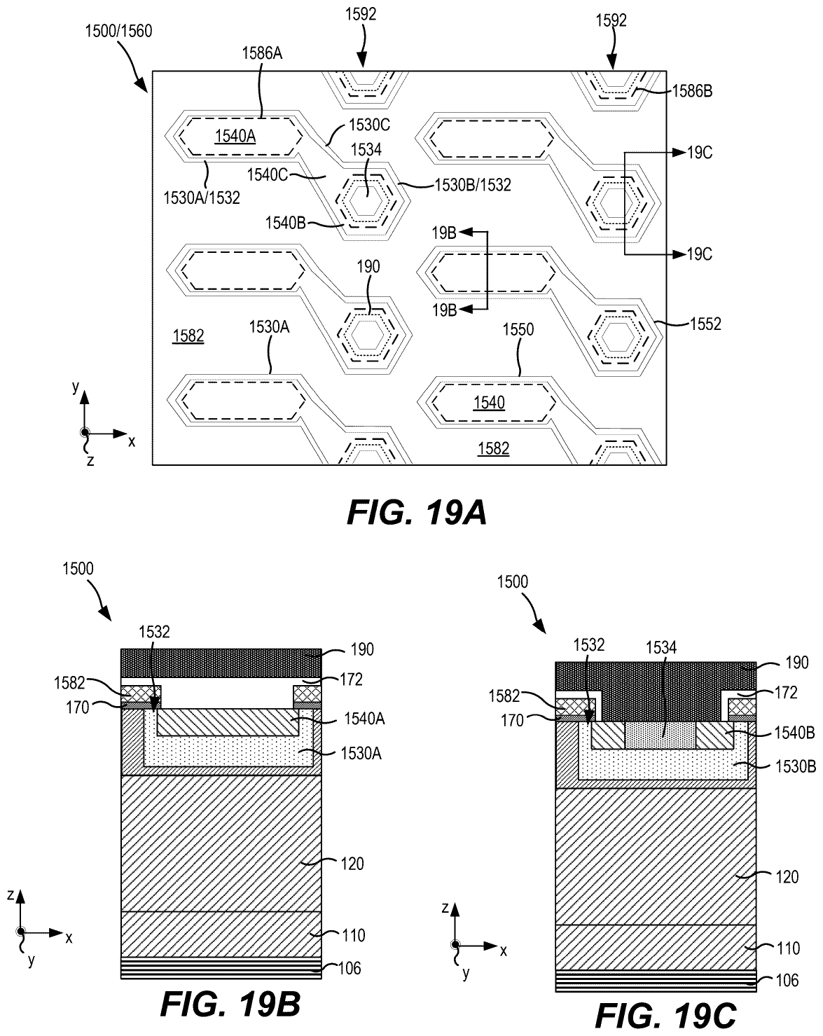

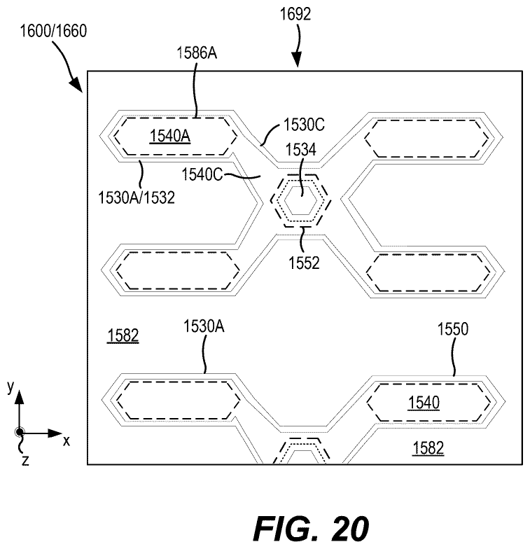

FIGS. 11A-11C and 13A-17B illustrate example planar gate vertical MOSFETS according to embodiments of the present invention that have “stripe” well designs, with either stripe gate electrode designs (FIGS. 11A-11C and 13A-13C) or mesh gate electrode designs (FIGS. 14A-14C, 15A-15C, 16A-16C, 17A and 17B). It will be appreciated that embodiments of the present invention are not limited thereto. In particular, FIGS. 19A-19C and 20 illustrate two planar gate vertical MOSFET according to embodiments of the present invention that have hexagonal cellular configurations as opposed to “stripe” cell layouts. Before discussing the MOSFETs of FIGS. 19A-20, it is helpful to discuss the layout and operation of a conventional planar gate vertical MOSFET that has a hexagonal cellular configuration. FIGS. 18A-18B illustrate one such conventional planar gate vertical MOSFET 1400. In particular, FIG. 18A is a schematic plan view of an upper surface of a semiconductor layer structure 1460 of power MOSFET 1400, while FIG. 18B is a schematic cross-sectional view of power MOSFET 1400 taken along line 18B-18B of FIG. 18A. In FIG. 18B, the gate and source metallization and an inter-metal dielectric layer that are omitted in FIG. 18A are illustrated to provide context.

As shown in FIGS. 18A-18B, in conventional power MOSFET 1400, a plurality of p-wells 1430 are formed in the upper surface of a semiconductor layer structure 1460, where each p-well 1430 has an irregular hexagonal ring shape when power MOSFET 1400 is viewed from above. The lower portion of each p-well 1430 may have an irregular hexagonal shape when viewed from above (as opposed to an irregular hexagonal ring shape). Highly doped n-type source regions 1440 are formed in the upper portion of each p-well 1430, where each source region 1440 also has an irregular hexagonal ring shape when MOSFET 1400 is viewed from above. Highly doped p-type well contact regions 1434 are formed in the middle of each source region 1440. The well contact regions 1434 electrically connect the p-wells 1430 to the source metallization 190. Each p-well 1430 having a respective source region 1440 and well contact region 1434 therein forms a “cell” of the hexagonal cell structure of power MOSFET 1400. The dotted lines in FIG. 14A show where the source metallization 190 contacts the semiconductor layer structure 1460. As shown, the source metallization 190 contacts each well contact region 1434 and the inner portion of each source region 1440. The dashed lines in FIG. 18A show where the gate electrode 1482 of power MOSFET 1400 is formed on the upper surface of the semiconductor layer structure 1460 (with a gate dielectric layer 170 between the gate electrode 1482 and the semiconductor layer structure 1460). As shown, the gate electrode 1482 may cover the entirety of the upper surface of the active region of the MOSFET 1400 except for the regions where the source metallization 190 contacts the semiconductor layer structure 1460 and small buffer regions where an intermetal dielectric layer 172 (see FIG. 18B) is formed that isolates the gate electrode 1482 from the source metallization 190.

As can be seen in FIG. 18B, the gate electrode 1482 vertically overlaps the outer portion of each source region 1440, the outer portion of each p-well 1430, and the JFET regions 1424 that are formed in between adjacent p-wells 1430. The upper region of the outer portion of each p-well 1430 acts as a channel region 1432 in that current can flow through these regions when power MOSFET 1400 is biased for on-state operation In particular, when a bias voltage is applied to the gate electrode 1482, the upper region of the outer portion of each p-well 1430 (i.e., the channel region 1432) is inverted, allowing current to flow from the source metallization 190 to the source regions 1440, through the channel regions 1432 of each p-well 1430, and into the JFET regions 1424. The current flows from the JFET regions 1424 to the drift region 120, into the substrate 110, and then into the drain contact 106.

FIGS. 19A-19C illustrate a planar gate vertical power MOSFET 1500 according to still further embodiments of the present invention that has a hexagonal cell structure. In particular, FIG. 19A is a schematic plan view of an upper surface of a semiconductor layer structure 1560 of power MOSFET 1500. FIGS. 19B and 19C are schematic cross-sectional views of power MOSFET 1500 taken along lines 19B-19B and 19C-19C, respectively, of FIG. 19A. While the gate electrode 1582 and the source metallization 190 are not shown in FIG. 19A, the region of the upper surface of the semiconductor layer structure 1560 of power MOSFET 1500 that is covered by the gate electrode 1582 is indicated in FIG. 19A using dashed lines, and the locations where the source metallization 190 directly contacts the semiconductor layer structure 1560 are indicated in FIG. 19A using dotted lines.

As shown in FIG. 19A, power MOSFET 1500 includes a plurality of hexagonal cells 1550. The hexagonal cells 1550 are disposed in columns that extend in the y-direction. Each hexagonal cell 1550 comprises a first p-well 1530A that has an irregular hexagon shape, and a first n-type source region 1540A that also has an irregular hexagon shape that is formed in an upper portion of the first p-well 1530A. As shown by the dashed lines in FIG. 19A, the gate electrode 1582 includes a plurality of first openings 1586A that expose the upper surface of the semiconductor layer structure 1560 over portions of the hexagonal cells 1550. The first openings 1586A are sized so that the gate electrode 1582 extends over the outer portion of each first p-well 1530A (i.e., the portion of each p-well that surrounds the first source region 1540A) and also extends over the outer portion of each first source region 1540A, while the inner portion of each first source region 1540A is exposed through the respective first openings 1586A. The upper portions of the first p-wells 1530A that are visible in FIG. 19A act as first channel regions 1532A during on-state operation.

As shown by additional of the dashed lines in FIG. 19A, the gate electrode 1582 further includes a plurality of second openings 1586B that expose the upper surface of the semiconductor layer structure 1560 over portions of a plurality of hexagonal contact areas 1552. These contact areas 1592 are arranged in columns to form a plurality of ohmic lines 1592. Each ohmic line 1592 comprises a plurality of hexagonal contact areas 1552 in the upper surface of the semiconductor layer structure 1560 that comprise the regions of the semiconductor layer structure 1560 that are directly contacted by the source metallization 190. Each hexagonal contact area 1552 comprises a second p-well 1530B that has a regular hexagon shape, a second n-type source region 1540B that also has a regular hexagon shape that is formed in an upper portion of the second p-well 1530B, and a well contact region 1534 that has a regular hexagon shape that is formed in an upper portion of the second source region 1540B. As shown by the dashed lines in FIG. 19A, the gate electrode 1582 extends over the outer portion of each second p-well 1530B (i.e., the portion of each p-well 1530B that surrounds the second source region 1540B) and also extends over the outer portion of each second source region 1540B. The upper portions of the second p-wells 1530B that are visible in FIG. 19A act as second channel regions 1532B during on-state operation. As shown by the dotted lines in FIG. 19A, the source metallization 190 directly contacts the well contact region 1534 and the inner portion of each second source region 1540B.

As is further shown in FIG. 19A, p-well extensions 1530C are formed that connect each first p-well 1530A to a respective one of the second p-wells 1530B. In addition, a respective source region extension 1540C is formed in each p-well extension 1530C. Each source region extension 1540C physically and electrically connects a respective one of the first source regions 1540A to a respective one of the second source regions 1540B. It should be noted that a channel region 1532 is not provided along the side of each hexagonal cell 1550 that faces the p-well and source regions extensions 1530C, 1540C, and that a channel region 1532 also is not provided along the side of each hexagonal contact area 1552 that faces the p-well and source regions extensions 1530C, 1540C. As shown in FIG. 19A, the ohmic lines 1592 are offset from the columns of hexagonal cells 1550 in the x-direction.

When an appropriate gate bias voltage is applied to power MOSFET 1500, current flows through the source metallization 190 into the semiconductor layer structure 1560 in the hexagonal contact areas 1552 (as these are the only regions in the device where the source metallization 190 directly contacts the semiconductor layer structure 1560). The current flows into the second source regions 1540B and then flows into the source region extensions 1540C, and from there into the first source regions 1540A. Thus, it can be seen that the source region extensions 1540C provide a current path that allows the on-state current to flow into the hexagonal cells 1550. The p-well extensions 1530C electrically connect the first p-wells 1530A to the second p-wells 1530B and to the well contact regions 1534.

Since the well contact regions 1534 are only formed in the hexagonal contact areas 1552 that form the ohmic lines 1592 and are not formed in the hexagonal cells 1550, the extent of each hexagonal cell 1550 in the y-direction may be reduced, as there is no need to form contact holes for the source metallization 190 above the hexagonal cells 1550, and there is no need for an insulating layer lining such contact holes. As such, all else being equal, the density of hexagonal cells 1550 may be increased as compared to the hexagonal cell density in conventional power MOSFET 1400 of FIGS. 18A-18B. The hexagonal contact areas 1552 may have a larger extent in the y-direction. Channel regions 1532 are provided around most of the periphery of each hexagonal cell 1550 and of each hexagonal contact region 1552.

As the above description makes clear, MOSFET 1500 uses the same technique of moving the ohmic lines away from at least some of the channel regions to increase the amount of channel area within the device. In this embodiment, channel regions are provided around five of the six sides of each hexagonal contact region 1552 to increase the total amount of channel area. Since the source metallization 190 does not contact the semiconductor layer structure 1560 within the hexagonal cell regions 1550, the extent of each hexagonal cell region 1550 in the y-direction may be reduced significantly, allowing more cells to be formed per unit area. Thus, FIGS. 19A-19C illustrate how the techniques disclosed herein may also be used to improve the performance of power MOSFETS having a cell configuration. While not shown in the figures, it will be appreciated that in a modified embodiment of power MOSFET 1500, a silicide layer may be formed on the upper surfaces of the first source regions 1540A, the second source regions 1540B and the source region extensions 1540C to provide a low-resistance path for the lateral on-state current flow through the source regions 1540. This allows the on-state current to have a very low-resistance path from the ohmic lines 1592 to the hexagonal cells 1550.

It will also be appreciated that many modifications may be made to power MOSFET 1500 without departing from the present inventive concepts. For example, the cells 1550 and/or the contact regions 1552 may have different shapes than shown (e.g., circular, octagons, rectangles, etc.). Likewise, each hexagonal contact region 1552 may connect to more than one hexagonal cell 1550. As another example, the number of ohmic lines 1592 may differ from the number of columns of hexagonal cells 1550. For example, in another embodiment, there may be about twice as many columns each of hexagonal cells 1550 as there are ohmic lines 1592, and each contact region 1552 may connect to two hexagonal cells 1550 that are on either side of the contact region in the x-direction. Many other modifications are possible.

Still referring to FIGS. 19A-19C, it can be seen that a semiconductor device is provided in the form of power MOSFET 1500 that comprises a semiconductor layer structure 1560, a gate electrode 1582 on the semiconductor layer structure 1560, a gate oxide layer 170 interposed in between the gate electrode 1582 and the semiconductor layer structure 1560, an intermetal dielectric layer 172 on the gate electrode 1582, and a source metallization layer 190 on the intermetal dielectric layer 172 and the semiconductor layer structure 1582. The gate electrode 1582 has a plurality of first openings 1586A that each have a first size and a plurality of second openings 1586B that each have a second size that is different than the first size.

The semiconductor layer structure 1560 comprises a drift region 120 having a first conductivity type (here n-type), a plurality of source regions 1540 having the first conductivity type, a plurality of well regions 1530 having a second conductivity type between the drift region 120 and the respective source regions 1540, and a plurality of well contact regions 1534 having the second conductivity type in upper portions of the respective well regions 1530.

The first openings 1586A may only expose upper portions of respective ones of the source regions 1540. The source metallization 190 may directly contact the semiconductor layer structure 1560 through the second openings 1586B. The source metallization 190 may be separated from portions of the semiconductor layer structure 1560 that are exposed by the first openings 1586A by a dielectric layer 172. Power MOSFET 1500 may optionally include a silicide layer 196 that directly contacts portions of the semiconductor layer structure 1560 that are exposed by the first openings 1586A. The contact regions 1534 may be exposed through respective ones of the second openings 1586B.

The second openings 1586B may be arranged in a plurality of columns that extend in a second direction (here, the y-direction). Each first opening 1586A may have a longitudinal axis that extends in a first direction (here, the x-direction) that is different than the second direction. Each well region 1530 may extend below at least one of the first openings 1586A and at least one of the second openings 1586B when the semiconductor device 1500 is viewed from above.

FIG. 20 is a schematic plan view of the semiconductor layer structure of a power MOSFET 1600 that is a modified version of power MOSFET of FIGS. 19A-19C. As can be seen by comparing FIG. 20 to FIG. 19A, the difference between the two power MOSFETs is that each first well region 1530A in power MOSFET 1500 is physically and electrically connected to a respective one of the contact areas 1552, while in power MOSFET 1600, four first well regions 1530A are physically and electrically connected to each contact area 1552. As a result, the number of ohmic lines 1692 included in power MOSFET 1600 may be reduced by half as compared to power MOSFET 1500, and the density of contact areas 1552 in each ohmic line 1692 may also be reduced by half in power MOSFET 1600 as compared to power MOSFET 1500.

In the description above, each example embodiment has a certain conductivity type. It will be appreciated that opposite conductivity type devices may be formed by simply reversing the conductivity of the n-type and p-type layers in each of the above embodiments. Thus, it will be appreciated that the present invention covers both n-channel and p-channel devices for each different device structure (e.g., MOSFET, IGBT, etc.).

The present invention has primarily been discussed above with respect to silicon carbide based power semiconductor devices. It will be appreciated, however, that silicon carbide is used herein as an example and that the devices discussed herein may be formed in any appropriate wide band-gap semiconductor material system. As an example, gallium nitride based semiconductor materials (e.g., gallium nitride, aluminum gallium nitride, etc.) may be used instead of silicon carbide in any of the embodiments described above.

References are made herein to a first element extending deeper into a semiconductor layer structure of a gate trench semiconductor device than a second element. The depth that an element extends into a semiconductor layer structure refers to a distance that the element extends from an upper surface of the semiconductor layer structure, where the upper surface is the surface from which the gate trenches extend into the semiconductor layer structure. Thus, if a first element extends deeper into a semiconductor layer structure than a second element, this means that a lowermost surface of the first element is farther from the upper surface of the semiconductor layer structure than is a lowermost surface of the second element. In the embodiments discussed above, the depth is the distance in the z-direction from the uppermost surface of the semiconductor layer structure.

Embodiments of the present invention have been described above with reference to the accompanying drawings, in which embodiments of the invention are shown. It will be appreciated, however, that this invention may, however, be embodied in many different forms and should not be construed as limited to the embodiments set forth above. Rather, these embodiments are provided so that this disclosure will be thorough and complete, and will fully convey the scope of the invention to those skilled in the art. Like numbers refer to like elements throughout.

Herein, the term “plurality” means two or more. Herein, “substantially” means within +/−10% unless otherwise indicated.

As used herein, two elements of a semiconductor device are considered to “vertically overlap” if an axis that is perpendicular to the major surfaces of a semiconductor layer structure of the semiconductor device intersects both elements.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Embodiments of the invention are also described with reference to a flow chart. It will be appreciated that the steps shown in the flow chart need not be performed in the order shown.

Herein, references to a region, layer or the like “comprising” a first periodic table element (e.g., silicon) means that the region, layer or the like includes either the recited periodic table element or compounds that include the periodic table element (e.g., silicon carbide). Such references, however, do not include unintentional impurities or intentionally added impurities such as dopant impurities that may be present but are less than 1% by atomic weight of the material forming the layer, region or the like. In contrast, references that a region, layer or the like “is” a first periodic table element (e.g., silicon) means that the region, layer or the like only includes the recited periodic table element and any unintentional or intentionally added impurities that are less than 1% by atomic weight of the material forming the layer, region or the like.

Some embodiments of the invention are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes.

Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments of the invention and, although specific terms are employed, they are used in a generic and descriptive sense only and not for purposes of limitation, the scope of the invention being set forth in the following claims.

1-19. (canceled)

20. A semiconductor device, comprising:
a semiconductor layer structure comprising a drift region having a first conductivity type, a source region having the first conductivity type and a well region having a second conductivity type between the drift region and the source region
wherein the source region has a U-shape when the semiconductor device is viewed from above.

21. The semiconductor device of claim 20, wherein the semiconductor layer structure further comprises a well contact region having the second conductivity type within the source region.

22. The semiconductor device of claim 21, wherein the combination of the source region and the well region has a U-shape when the semiconductor device is viewed from above, and the source region is formed within an upper portion of the well region.

23. The semiconductor device of claim 20, wherein the source region has first and second leg segments and a base segment that extends in between and physically connects to the first and second leg segments when the semiconductor device is viewed from above, and the semiconductor layer structure further comprises a JFET region having the first conductivity type that is positioned in between first and second leg segments.

24. (canceled)

25. The semiconductor device of claim 20, wherein the source region is one of a plurality of source regions and the well region is one of a plurality of well regions, wherein each of the plurality of source regions has a U-shape when the semiconductor device is viewed from above.

26. The semiconductor device of claim 25, wherein the source regions arranged in rows and columns when the semiconductor device is viewed from above.

27. (canceled)

28. The semiconductor device of claim 26, wherein the well contact regions in a first of the columns of source regions have longitudinal axes that extend along a first axis, the well contact regions and portions of the source regions in which the well contact regions are positioned forming a first ohmic line that comprises a plurality of spaced-apart ohmic line segments.

29. The semiconductor device of claim 28, further comprising a source metallization on an upper surface of the semiconductor layer structure, the source metallization contacting the semiconductor layer structure along the first ohmic line.

30-33. (canceled)

34. A semiconductor device, comprising:
a semiconductor layer structure comprising a drift region having a first conductivity type, a source region having the first conductivity type and a well region having a second conductivity type between the drift region and the source region,
wherein the drift region comprises a JFET region segment that extends along a first longitudinal axis, and the well region directly contacts at least three, but less than all, of a plurality of sidewalls of the JFET region segment.

35. The semiconductor device of claim 34, wherein a channel region that is configured to be inverted during on-state operation of the semiconductor device is defined in the well region so that the channel region extends adjacent all of the at least three of the plurality of sidewalls of the JFET region segment.

36. (canceled)

37. The semiconductor device of claim 35, wherein the JFET region segment is part of a first JFET region that extends along the first longitudinal axis, the first JFET region comprising a plurality of JFET region segments.

38. The semiconductor device of claim 37, wherein the well region is one of a plurality of well regions, and wherein each of the well regions directly contacts at least three, but less than all, of a plurality of sidewalls of a respective one of the JFET region segments in the first JFET region.

39. The semiconductor device of claim 35, wherein an upper portion of the well region has first and second well leg segments that extend in parallel to the first longitudinal axis and a well base segment that extends between and connects to first ends of the first and second well leg segments when the semiconductor device is viewed from above, and wherein the JFET region segment is positioned in between the first and second well legs when the semiconductor device is viewed from above.

40. The semiconductor device of claim 39, wherein the source region has first and second source leg segments that extend in parallel to the first longitudinal axis and a source base segment that extends between and connects to first ends of the first and second source leg segments when the semiconductor device is viewed from above, and wherein the source is within an upper portion of the well region.

41-43. (canceled)

44. The semiconductor device of claim 39, further comprising a source metallization that comprises a silicide layer and a bulk metal layer on the silicide layer opposite the semiconductor layer structure, wherein the silicide layer that directly contacts the first and second source leg segments, and wherein a dielectric layer covers portions of the silicide layer that directly contact the first and second source leg segments so that the dielectric layer is in between the silicide layer and the source metallization.

45-62. (canceled)

63. A semiconductor device, comprising:
a semiconductor layer structure comprising a source region having a first conductivity type;
a silicide layer on the source region; and
a dielectric layer on the silicide layer so that the silicide layer is in between and directly contacts both the source region and the dielectric layer.

64. The semiconductor device of claim 63, further comprising a bulk source metallization layer, wherein the dielectric layer is in between the silicide layer and the bulk source metallization layer and directly contacts both the silicide layer and the bulk source metallization layer.

65. (canceled)

66. The semiconductor device of claim 63, wherein the semiconductor layer structure further comprises a drift region having the first conductivity type and a plurality of well regions having a second conductivity type on the drift region, wherein the source region is one of a plurality of sources region having the first conductivity type, and the source regions are formed in upper portions of the respective well regions.

67. The semiconductor device of claim 66, wherein the semiconductor layer structure further comprises a plurality of contact regions having the second conductivity type that are formed in the upper portions the respective well regions.

68. The semiconductor device of claim 67, wherein the silicide layer directly contacts a first of the well contact regions.

69. The semiconductor device of claim 66, wherein each source region has a U-shape when the semiconductor device is viewed from above.

70. (canceled)

71. The semiconductor device of claim 63, wherein the silicide layer is part of a source metallization, the source metallization further comprising a bulk source metallization layer, and wherein the dielectric layer is interposed between a portion of the bulk source metallization layer and the silicide layer.

72-76. (canceled)
